(19) United States
(12) Patent Application Publication
(10) Pub. No.: US 2026/0255575 A1
(43) Pub. Date: Aug. 27, 2026

(54) SEMICONDUCTOR MEMORY DEVICE INCLUDING SEMICONDUCTOR PATTERN

(71) Applicant: Samsung Electronics Co., Ltd., Suwon-si (KR)

(72) Inventor: Sungnam Lyu, Suwon-si (KR)

(73) Assignee: Samsung Electronics Co., Ltd., Suwon-si (KR)

(21) Appl. No.: 19/468,932

(22) Filed: Feb. 3, 2026

(30) Foreign Application Priority Data
Feb. 21, 2025 (KR) 10-2025-0023161

(51) Int. Cl. H10B 12/00

(52) U.S. Cl. CPC H10B 12/30; H10B 12/05

(57) ABSTRACT

Provided is a semiconductor memory device including a first semiconductor pattern extending in a first horizontal direction, a second semiconductor pattern having a horizontal width that is less than a horizontal width of the first semiconductor pattern in a second horizontal direction, being spaced apart from the first semiconductor pattern in the second horizontal direction, and extending in the first horizontal direction, the second horizontal direction being substantially orthogonal to the first horizontal direction, a gate structure surrounding the first semiconductor pattern and the second semiconductor pattern and extending in the second horizontal direction, a bit line connected to an end of the first semiconductor pattern in the first horizontal direction and extending in a vertical direction, and a capacitor structure connected to another end of the first semiconductor pattern in the first horizontal direction.

### CROSS-REFERENCE TO RELATED APPLICATIONS

This present application claims priority to and the benefit under 35 U.S.C. § 119(a)-(d) of Korean Patent Application No. 10-2025-0023161, filed on Feb. 21, 2025, in the Korean Intellectual Property Office, the entire disclosure of which is incorporated herein by reference.

### FIELD

The disclosed concepts relate to a semiconductor memory device, and more particularly, to a three-dimensional semiconductor memory device.

### BACKGROUND

As electronic products are required to have smaller sizes, multi-functions, and higher performance, high-capacity semiconductor memory devices are required, and an increased degree of integration is required to provide high-capacity semiconductor memory devices. Because the degree of integration of two-dimensional semiconductor memory devices of the related art is mainly determined by the area occupied by a unit memory cell, the degree of integration of two-dimensional semiconductor memory devices has increased but is still limited.

### SUMMARY

The disclosed concepts provide a three-dimensional semiconductor memory device having improved operational reliability.

According to aspects of the disclosed concepts, there is provided a semiconductor memory device including a first semiconductor pattern extending in a first horizontal direction, a second semiconductor pattern having a horizontal width that is less than a horizontal width of the first semiconductor pattern in a second horizontal direction, being spaced apart from the first semiconductor pattern in the second horizontal direction, and extending in the first horizontal direction, the second horizontal direction being substantially orthogonal to the first horizontal direction, a gate structure surrounding the first semiconductor pattern and the second semiconductor pattern and extending in the second horizontal direction, a bit line connected to an end of the first semiconductor pattern in the first horizontal direction and extending in a vertical direction, and a capacitor structure connected to another end of the first semiconductor pattern in the first horizontal direction, wherein the second semiconductor pattern is spaced apart from each of the bit line and the capacitor structure.

According to aspects of the disclosed concepts, there is provided a semiconductor memory device including a plurality of first semiconductor patterns each extending in a first horizontal direction and arranged spaced apart from one another in each of a second horizontal direction and a vertical direction, the second horizontal direction being substantially orthogonal to the first horizontal direction, a plurality of second semiconductor patterns each extending in the first horizontal direction, each having a horizontal width that is less than a horizontal width of each of the plurality of first semiconductor patterns in the second horizontal direction, arranged spaced apart from one another in each of the second horizontal direction and the vertical direction, and alternately arranged spaced apart from the plurality of first semiconductor patterns in the second horizontal direction, a plurality of gate structures surrounding the plurality of first semiconductor patterns and the plurality of second semiconductor patterns, each extending in the second horizontal direction, and arranged spaced apart from one another in the vertical direction, an interlayer insulating layer surrounding the plurality of first semiconductor patterns, the plurality of second semiconductor patterns, and the plurality of gate structures, a plurality of bit lines connected to ends of first semiconductor patterns arranged spaced apart from one another in the vertical direction, among the plurality of first semiconductor patterns, in the first horizontal direction, each extending in the vertical direction, and arranged spaced apart from one another in the second horizontal direction, a line trench filling insulating layer surrounding the plurality of bit lines, a plurality of capacitor structures connected to other ends of the plurality of first semiconductor patterns in the first horizontal direction, and a capacitor trench filling insulating layer surrounding the plurality of capacitor structures, wherein the plurality of second semiconductor patterns are spaced apart from the plurality of bit lines and the plurality of capacitor structures.

According to aspects of the disclosed concepts, there is provided a semiconductor memory device including a plurality of first semiconductor patterns each extending in a first horizontal direction and arranged spaced apart from one another in each of a second horizontal direction and a vertical direction, the second horizontal direction being substantially orthogonal to the first horizontal direction, a plurality of second semiconductor patterns each extending in the first horizontal direction, each having a horizontal width that is less than a horizontal width of each of the plurality of first semiconductor patterns in the second horizontal direction, arranged spaced apart from one another in each of the second horizontal direction and the vertical direction, and alternately arranged spaced apart from the plurality of first semiconductor patterns in the second horizontal direction, a plurality of gate structures surrounding the plurality of first semiconductor patterns and the plurality of second semiconductor patterns, each extending in the second horizontal direction, and arranged spaced apart from one another in the vertical direction, an interlayer insulating layer surrounding the plurality of first semiconductor patterns, the plurality of second semiconductor patterns, and the plurality of gate structures, a plurality of bit lines connected to ends of first semiconductor patterns arranged spaced apart from one another in the vertical direction, among the plurality of first semiconductor patterns, in the first horizontal direction, each extending in the vertical direction, and arranged spaced apart from one another in the second horizontal direction, a line trench filling insulating layer surrounding the plurality of bit lines, a plurality of capacitor structures connected to other ends of the plurality of first semiconductor patterns in the first horizontal direction, and a capacitor trench filling insulating layer surrounding the plurality of capacitor structures, wherein, in the first horizontal direction, ends of the plurality of second semiconductor patterns are in contact with the line trench filling insulating layer, and other ends of the plurality of second semiconductor patterns are in contact with the interlayer insulating layer.

According to aspects of the disclosed concepts, there is provided a method of manufacturing a semiconductor memory device, the method including forming a stacked structure by alternately forming a plurality of semiconductor layers and a plurality of sacrificial layers in a vertical direction, forming a plurality of first semiconductor layers and a plurality of second semiconductor layers by separating the plurality of semiconductor layers, the plurality of first semiconductor layers each extending in a first horizontal direction and arranged spaced apart from one another in each of a second horizontal direction and the vertical direction, the second horizontal direction being substantially orthogonal to the first horizontal direction, and the plurality of second semiconductor layers each extending in the first horizontal direction, each having a horizontal width that is less than a horizontal width of each of the plurality of first semiconductor layers in the second horizontal direction, arranged spaced apart from one another in each of the second horizontal direction and the vertical direction, and alternately arranged spaced apart from the plurality of first semiconductor layers in the second horizontal direction, removing the plurality of sacrificial layers, forming a plurality of first semiconductor patterns and a plurality of second semiconductor patterns by removing a portion of each of the plurality of first semiconductor layers and the plurality of second semiconductor layers, forming a plurality of gate structures surrounding the plurality of first semiconductor patterns and the plurality of second semiconductor patterns, each extending in the second horizontal direction, and arranged spaced apart from one another in the vertical direction; forming a plurality of bit lines connected to ends of first semiconductor patterns arranged spaced apart from one another in the vertical direction, among the plurality of first semiconductor patterns, in the first horizontal direction, being spaced apart from the plurality of second semiconductor patterns, each extending in the vertical direction, and arranged spaced apart from one another in the second horizontal direction, and forming a plurality of capacitor structures connected to other ends of the plurality of first semiconductor patterns in the first horizontal direction and being spaced apart from the plurality of second semiconductor patterns.

In embodiments, the forming of the plurality of first semiconductor layers and the plurality of second semiconductor layers by separating the plurality of semiconductor layers may include forming a plurality of trim spaces each penetrating the stacked structure and arranged spaced apart from one another in the second horizontal direction, and forming a line trench and a capacitor trench each extending in the second horizontal direction along one side and another side of the plurality of trim spaces in the first horizontal direction and each penetrating the stacked structure, the second horizontal direction being substantially orthogonal to the first horizontal direction.

In embodiments, in a plan view, each of the plurality of trim spaces may have a U-shape including a pair of separate trim spaces and a short-axis trim space, the pair of separate trim spaces extending in the first horizontal direction and being spaced apart from one another in the second horizontal direction, and the short-axis trim space connecting ends of the pair of separate trim spaces to one another in the first horizontal direction.

In embodiments, the forming of the line trench and the capacitor trench may include forming the capacitor trench on a side of the short-axis trim space connecting the ends of the pair of separate trim spaces of each of the plurality of trim spaces to one another in the first horizontal direction, and forming the line trench on a side of other ends of the pair of separate trim spaces of each of the plurality of trim spaces in the second horizontal direction.

In embodiments, the method may further include forming a first insulating layer filling the plurality of trim spaces, forming a second insulating layer filling a plurality of first removal spaces where the line trench, the capacitor trench, and the plurality of sacrificial layers have been removed, before forming the plurality of first semiconductor patterns and the plurality of second semiconductor patterns, removing a portion of the second insulating layer, the portion filling the line trench; after forming the plurality of gate structures, forming a plurality of gate recesses by removing portions of the plurality of gate structures, and before forming the plurality of bit lines, forming a third insulating layer filling the line trench and the plurality of gate recesses.

In embodiments, in the first horizontal direction, ends of the plurality of second semiconductor patterns may be in contact with the third insulating layer, and other ends of the plurality of second semiconductor patterns may be in contact with the first insulating layer.

In embodiments, each of the plurality of first semiconductor patterns may include a first portion, a second portion, and a third portion, the first portion being surrounded by one of the plurality of gate structures, the second portion being surrounded by the third insulating layer and connected to one of the plurality of bit lines, and the third portion being surrounded by the first insulating layer and the second insulating layer and connected to one of the plurality of capacitor structures, and each of the plurality of second semiconductor patterns may include a first dummy portion and a second dummy portion, the first dummy portion being surrounded by one of the plurality of gate structures, and the second dummy portion being surrounded by the third insulating layer, wherein, in the first horizontal direction, a length of the first dummy portion of each of the plurality of second semiconductor patterns may be less than a length of the first portion of each of the plurality of first semiconductor patterns, and, in the first horizontal direction, a length of the second dummy portion of each of the plurality of second semiconductor patterns may be equal to a length of the second portion of each of the plurality of first semiconductor patterns.

In embodiments, in the second horizontal direction, a horizontal width of the third portion of each of the plurality of first semiconductor patterns may be greater than each of a horizontal width of the first portion and a horizontal width of the second portion, and in the vertical direction, a thickness of the third portion of each of the plurality of first semiconductor patterns may be greater than each of a thickness of the first portion and a thickness of the second portion.

In embodiments, the forming of the plurality of first semiconductor patterns and the plurality of second semiconductor patterns may be performed such that in the first horizontal direction, ends of the plurality of first semiconductor patterns may be aligned with ends of the plurality of second semiconductor patterns in the second horizontal direction, and in the first horizontal direction, a length of each of the plurality of first semiconductor patterns may be greater than a length of each of the plurality of second semiconductor patterns.

In embodiments, the forming of the plurality of first semiconductor layers and the plurality of second semiconductor layers by separating the plurality of semiconductor layers may be performed such that in the first horizontal direction, a length of each of the plurality of first semiconductor patterns may be greater than a length of each of the plurality of second semiconductor patterns.

### BRIEF DESCRIPTION OF THE DRAWINGS

Embodiments will be more clearly understood from the following detailed description taken in conjunction with the accompanying drawings in which:

FIG. 1 is an equivalent circuit diagram illustrating a memory cell array of a semiconductor memory device according to embodiments;

FIG. 2 is a block diagram illustrating a semiconductor memory device according to embodiments;

FIGS. 3A, 3B, 3C, and 3D are diagrams illustrating a semiconductor memory device according to embodiments;

FIGS. 4A, 4B, 4C, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, 16A, 16B, and 16C are diagrams illustrating a method of manufacturing a semiconductor memory device, according to embodiments;

FIG. 17 is an equivalent circuit diagram illustrating a memory cell array of a semiconductor memory device according to embodiments; and

FIGS. 18A, 18B, and 18C are diagrams illustrating a semiconductor memory device according to embodiments.

### DETAILED DESCRIPTION

A three-dimensional semiconductor memory device, in which memory capacity is increased by stacking a plurality of memory cells in a vertical direction on a substrate, has been proposed.

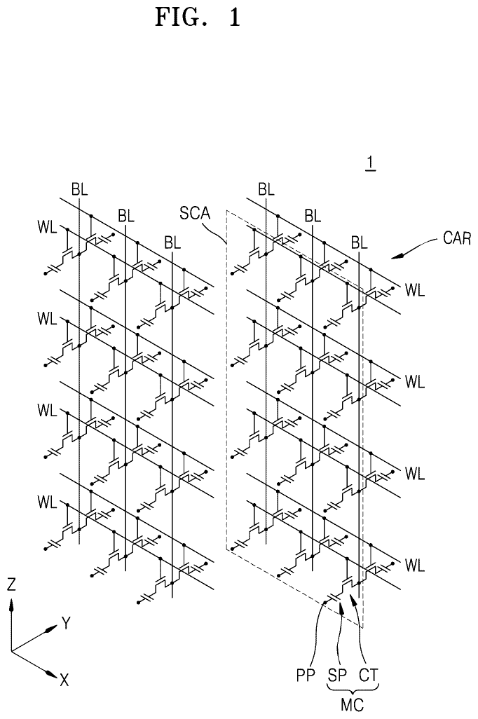

FIG. 1 is an equivalent circuit diagram illustrating a memory cell array of a semiconductor memory device 1 according to embodiments.

Referring to FIG. 1, a memory cell array CAR of the semiconductor memory device 1 according to embodiments may include a plurality of sub-cell arrays SCA. The sub-cell array SCA may include a plurality of bit lines BL, a plurality of word lines WL, and a plurality of memory cells MC. Each of the plurality of memory cells MC may include a cell transistor CT and an information storage element SP. One cell transistor CT may be arranged between one word line WL and one bit line BL. The information storage element SP may be a memory element capable of storing data.

The word line WL may be a conductive pattern (e.g., a metal line) arranged above a substrate and be spaced apart from the substrate. Each of the plurality of word lines WL may extend in a first horizontal direction (X direction). The word lines WL within one sub-cell array SCA may be spaced apart from one another in a vertical direction (Z direction). Each of the bit lines BL may extend in the vertical direction (Z direction) from the substrate. The bit lines BL within one sub-cell array SCA may be spaced apart from one another in the first horizontal direction (X direction).

In the memory cell array CAR of the semiconductor memory device 1, the plurality of word lines WL may extend in the first horizontal direction (X direction), and may be spaced apart from one another in each of a second horizontal direction (Y direction) and the vertical direction (Z direction). In the memory cell array CAR of the semiconductor memory device 1, the plurality of bit lines BL may extend in the vertical direction (Z direction), and may be spaced apart from one another in each of the first horizontal direction (X direction) and the second horizontal direction (Y direction).

In some embodiments, the information storage element SP may be a memory element using a capacitor, a memory element using a magnetic tunnel junction pattern, or a memory element using a variable resistor including a phase change material. For example, the memory cell MC may be a dynamic random-access memory (DRAM) cell, and the information storage element SP may be a capacitor. In another embodiment, the information storage element SP may be a transistor capable of storing data together with the cell transistor CT.

A gate of the cell transistor CT may be connected to the word line WL, and a source region of the cell transistor CT may be connected to the bit line BL. The information storage element SP may be connected to a drain region of the cell transistor CT. In some embodiments, the information storage element SP may be a capacitor including a first electrode, a second electrode, and a capacitor dielectric layer provided between the first electrode and the second electrode, wherein the first electrode of the capacitor may be connected to the drain region of the cell transistor CT, and the second electrode of the capacitor may be connected to a ground wiring PP. In some embodiments, the second electrode of the capacitor may be a portion of the ground wiring PP.

The memory cell array CAR of the semiconductor memory device 1 may include a plurality of sub-cell arrays SCA each including: a plurality of memory cells MC arranged spaced apart from one another in rows and columns in the first horizontal direction (X direction) and the vertical direction (Z direction), respectively; a plurality of bit lines BL connected to the cell transistors CT of the memory cells MC, extending in the vertical direction (Z direction), and arranged spaced apart from one another in the first horizontal direction (X direction), the memory cells MC being arranged in the vertical direction (Z direction); and a plurality of word lines WL extending in the first horizontal direction (X direction) and arranged spaced apart from one another in the vertical direction (Z direction), wherein the plurality of sub-cell arrays SCA may be arranged in the second horizontal direction (Y direction). The semiconductor memory device 1 may include a plurality of memory cell arrays CAR.

The first horizontal direction (X direction), the second horizontal direction (Y direction), and the vertical direction (Z direction) may be referred to as a first direction, a second direction, and a third direction, respectively. Alternatively, the first horizontal direction (X direction), the vertical direction (Z direction), and the second horizontal direction (Y direction) may be referred to as a first direction, a second direction, and a third direction, respectively. The first direction, the second direction, and the third direction may be substantially orthogonal to one another.

Two sub-cell arrays SCA adjacent to one another in the second horizontal direction (Y direction) may share bit lines BL. To the bit lines BL shared by the two sub-cell arrays SCA adjacent to one another in the second horizontal direction (Y direction), the source regions of the cell transistors CT respectively included in the two sub-cell arrays SCA may be connected. From each of the bit lines BL shared by the two sub-cell arrays SCA, the source regions and drain regions of the respective cell transistors CT and the respective information storage elements SP of the two sub-cell arrays SCA may be arranged in opposite directions. For example, the cell transistor CT of one of the two sub-cell arrays SCA and the cell transistor CT of the other sub-cell array SCA may be connected to one bit line BL shared by the two sub-cell arrays SCA. The source region of the cell transistor CT, the drain region of the cell transistor CT, and the information storage element SP of one sub-cell array SCA may be sequentially arranged in the second horizontal direction (Y direction). The source region of the cell transistor CT, the drain region of the cell transistor CT, and the information storage element SP of the other sub-cell array SCA may be sequentially arranged in a direction opposite to the second horizontal direction (Y direction). For example, between a pair of bit lines BL sequentially arranged adjacent to one another in the second horizontal direction (Y direction), among the plurality of bit lines BL, two memory cells MC may be arranged at the same vertical level in the second horizontal direction (Y direction).

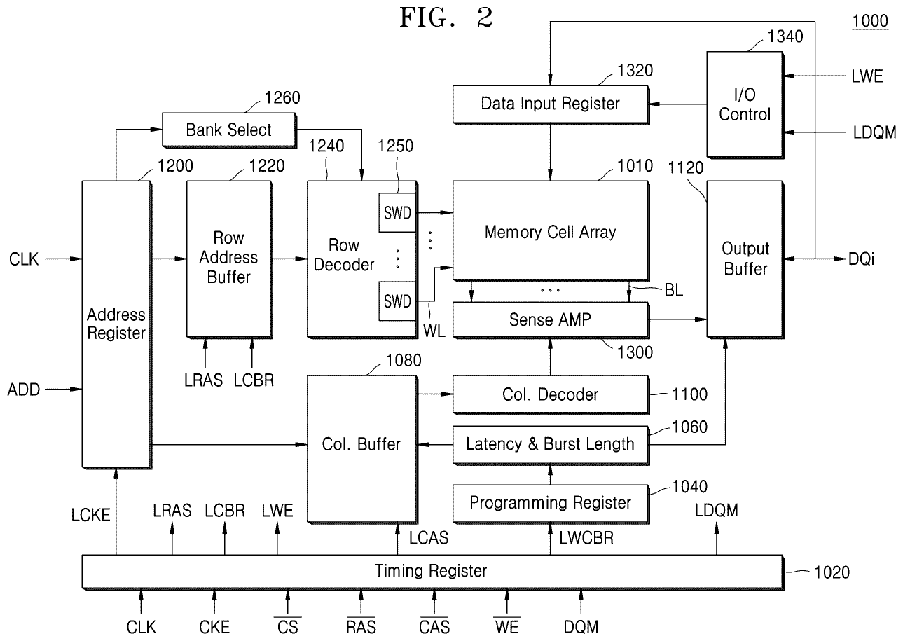

FIG. 2 is a block diagram illustrating a semiconductor memory device 1000 according to embodiments.

Referring to FIG. 2, the semiconductor memory device 1000 may include a memory cell array 1010 including a DRAM cell, which is a memory cell, and various circuit blocks for driving the DRAM cell. For example, a timing register 1020 may be activated when a chip select signal CS-bar is changed from an inactive level (e.g., logic high) to an active level (e.g., logic low). The timing register 1020 may receive command signals, such as a clock signal CLK, a clock enable signal CKE, a chip select signal CS-bar, a row address strobe signal RAS-bar, a column address strobe signal CAS-bar, a write enable signal WE-bar, and a data input/output mask signal DQM, from the outside, and may process the received command signals to generate various internal command signals, such as LCKE, LRAS, LCBR, LWE, LCAS, LWCBR, and LDQM, for controlling the circuit blocks.

Some of the internal command signals generated by the timing register 1020 may be stored in a programming register 1040. For example, latency information or burst length information associated with data output may be stored in the programming register 1040. The internal command signals stored in the programming register 1040 may be provided to a latency/burst length controller 1060, and the latency/burst length controller 1060 may provide a control signal for controlling the latency or burst length of data output to a column decoder 1100 or an output buffer 1120 through a column address buffer 1080.

An address register 1200 may receive a clock signal CLK and an address signal ADD from the outside. A row address signal may be provided to a row decoder 1240 through a row address buffer 1220. Also, a column address signal may be provided to the column decoder 1100 through the column address buffer 1080. The row address buffer 1220 may further receive a refresh address signal generated by a refresh counter in response to refresh commands LRAS and LCBR, and may provide one of the row address signal and the refresh address signal to the row decoder 1240. Also, the address register 1200 may provide a bank signal for selecting a bank to a bank selector 1260.

The row decoder 1240 may decode the row address signal or the refresh address signal input from the row address buffer 1220. The row decoder 1240 may include a plurality of sub-word line drivers 1250. The sub-word line driver 1250 may activate a word line WL of the memory cell array 1010. The sub-word line drivers 1250 may be arranged in blocks at certain intervals within the row decoder 1240 so as to be adjacent to the memory cell array 1010. For example, the sub-word line driver 1250 may be arranged adjacent to an end of the memory cell array 1010 so as to be perpendicular to a sense amplifier 1300.

The column decoder 1100 may decode the column address signal, and may perform a selection operation on a bit line BL of the memory cell array 1010. For example, a column selection line may be applied to the semiconductor memory device 1000, and a selection operation may be performed through the column selection line.

The sense amplifier 1300 may amplify data of a memory cell selected by the row decoder 1240 and the column decoder 1100, and may provide the amplified data to the output buffer 1120. The output buffer 1120 may output output data DQi. The output buffer 1120 may output output data DQi. The output data DQi to be written to a data cell may be provided to the memory cell array 1010 through a data input register 1320, and an input/output controller 1340 may control a data transmission operation through the data input register 1320.

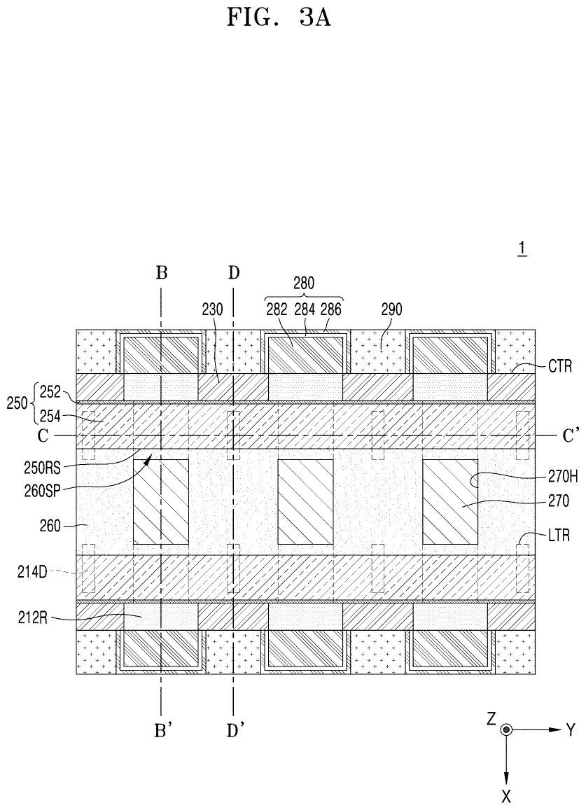

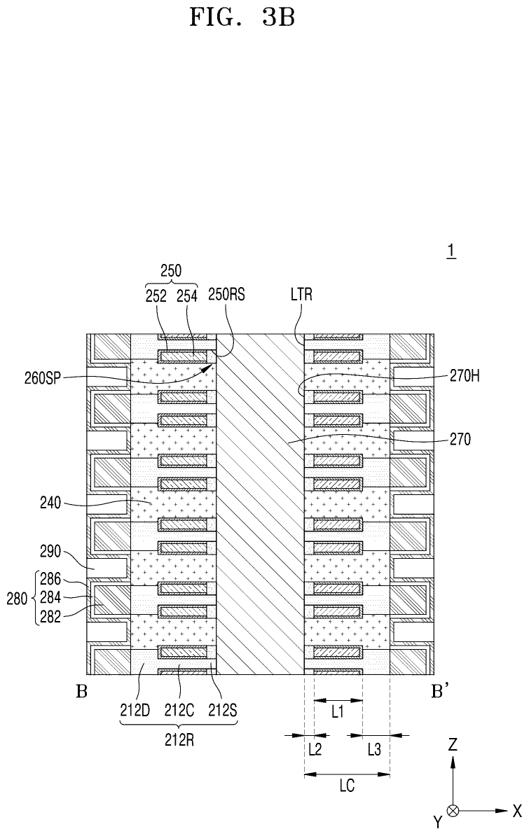

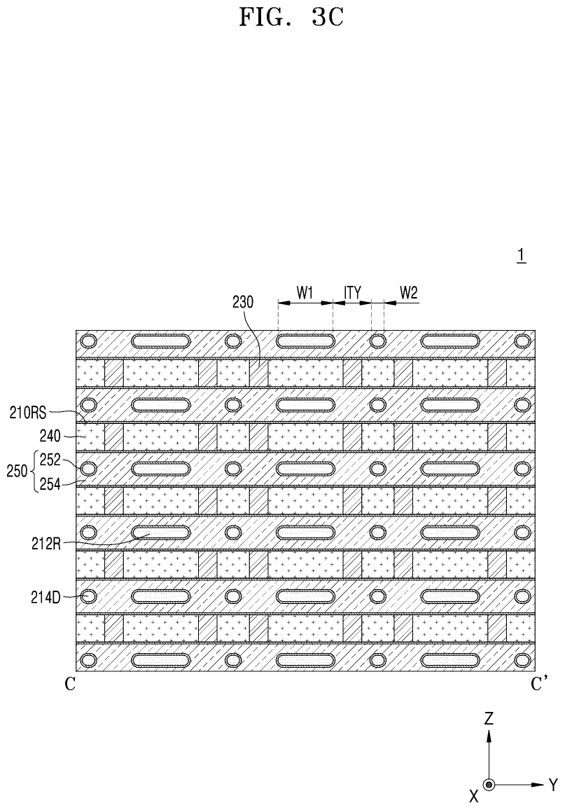

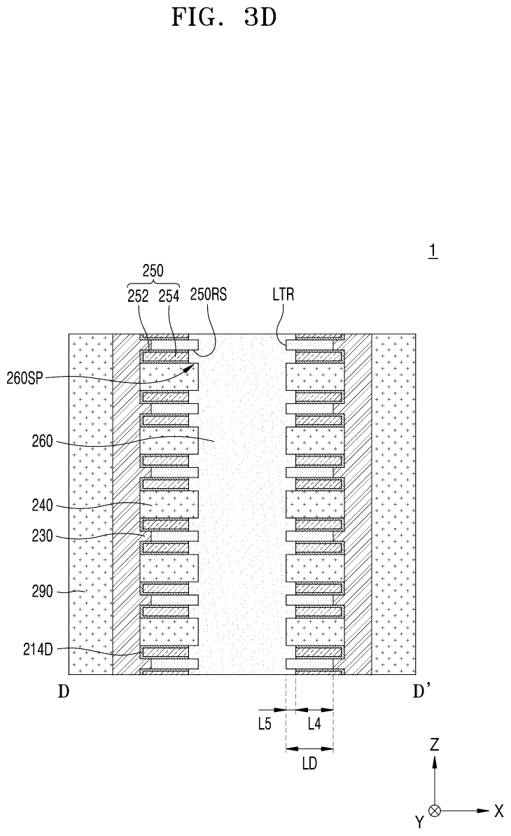

FIGS. 3A, 3B, 3C, and 3D are diagrams illustrating the semiconductor memory device 1 according to embodiments. In detail, FIG. 3A is a plan layout view illustrating main components of the semiconductor memory device 1, FIG. 3B is a cross-sectional view of the semiconductor memory device 1, taken along line B-B′ of FIG. 3A, FIG. 3C is a cross-sectional view of the semiconductor memory device 1, taken along line C-C′ of FIG. 3A, and FIG. 3D is a cross-sectional view of the semiconductor memory device 1, taken along line D-D′ of FIG. 3A.

Referring to FIGS. 3A, 3B, 3C, and 3D, the semiconductor memory device 1 may include a plurality of first semiconductor patterns 212R, a plurality of second semiconductor patterns 214D, a plurality of gate dielectric layers 252 surrounding at least portions of the plurality of first semiconductor patterns 212R and the plurality of second semiconductor patterns 214D, a plurality of gate electrodes 254 surrounding at least portions of the plurality of first semiconductor patterns 212R and the plurality of second semiconductor patterns 214D with the plurality of gate dielectric layers 252 therebetween, a plurality of bit lines 270 connected to ends of the plurality of first semiconductor patterns 212R, and a plurality of capacitor structures 280 connected to the other ends of the plurality of first semiconductor patterns 212R.

Each of the plurality of first semiconductor patterns 212R and the plurality of second semiconductor patterns 214D may extend in the first horizontal direction (X direction). Each of the plurality of gate electrodes 254 may extend in the second horizontal direction (Y direction). The second horizontal direction (Y direction) may be substantially orthogonal to the first horizontal direction (X direction). The plurality of first semiconductor patterns 212R may be referred to as cell semiconductor patterns, and the plurality of second semiconductor patterns 214D may be referred to as dummy semiconductor patterns. The plurality of bit lines 270 may be connected to ends of the plurality of first semiconductor patterns 212R in the first horizontal direction (X direction), and the plurality of capacitor structures 280 may be connected to the other ends of the plurality of first semiconductor patterns 212R in the first horizontal direction (X direction). The gate electrode 254 may be the word line WL shown in FIG. 1. The bit line 270 may be the bit line BL shown in FIG. 1. The capacitor structure 280 may be the information storage element SP shown in FIG. 1. The first semiconductor pattern 212R, the gate dielectric layer 252, the gate electrode 254, and the bit line 270 may form the cell transistor CT shown in FIG. 1.

The plurality of first semiconductor patterns 212R may be arranged spaced apart from one another in each of the first horizontal direction (X direction), the second horizontal direction (Y direction), and the vertical direction (Z direction). The plurality of first semiconductor patterns 212R may have matrix forms that are arranged in a line in each of the first horizontal direction (X direction) and the second horizontal direction (Y direction) in a plan view, and may be arranged to be aligned in the vertical direction (Z direction). The plurality of second semiconductor patterns 214D may be arranged spaced apart from one another in each of the first horizontal direction (X direction), the second horizontal direction (Y direction), and the vertical direction (Z direction). The plurality of second semiconductor patterns 214D may have matrix forms that are arranged in a line in each of the first horizontal direction (X direction) and the second horizontal direction (Y direction) in a plan view, and may be arranged to be aligned in the vertical direction (Z direction). The second semiconductor pattern 214D may be arranged between a pair of first semiconductor patterns 212R adjacent to one another in the second horizontal direction (Y direction). For example, the first semiconductor patterns 212R and the second semiconductor patterns 214D may be alternately arranged spaced apart from one another in the second horizontal direction (Y direction).

Each of the first semiconductor pattern 212R and the second semiconductor pattern 214D may include a semiconductor material. In some embodiments, each of the first semiconductor pattern 212R and the second semiconductor pattern 214D may include silicon (Si). In some embodiments, each of the first semiconductor pattern 212R and the second semiconductor pattern 214D may include a single crystal semiconductor material. For example, each of the first semiconductor pattern 212R and the second semiconductor pattern 214D may include single crystal Si. In some other embodiments, each of the first semiconductor pattern 212R and the second semiconductor pattern 214D may include a 2D semiconductor material or an oxide semiconductor material. For example, the 2D semiconductor material may include MOS₂, WSe₂, graphene, carbon nano tubes, or a combination thereof. For example, the oxide semiconductor material may include InₓGa_{y}Zn_{z}O, tin (Sn)-doped InₓGa_{y}Zn_{z}O, InₓGa_{y}Si_{z}O, InₓSn_{y}Zn_{z}O, InₓZn_{y}O, tugsten (W)-doped InO, InZnₓO, ZnₓSn_{y}O, ZnₓO_{y}N, ZrₓZn_{y}Sn_{z}O, yttrium (Y)-doped ZnO, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. In some embodiments, each of the first semiconductor pattern 212R and the second semiconductor pattern 214D may have the same impurity concentration as a whole, or may be an intrinsic semiconductor in which no impurities are implanted as a whole. For example, each of the first semiconductor pattern 212R and the second semiconductor pattern 214D may have a junctionless structure. The first semiconductor pattern 212R and the second semiconductor pattern 214D may include the same material.

The first semiconductor pattern 212R may include a first portion 212C, a second portion 212S, and a third portion 212D. The second portion 212S and the third portion 212D may be respectively located on both sides of the first portion 212C in the first horizontal direction (X direction). The second portion 212S, the first portion 212C, and the third portion 212D may be sequentially arranged in the first horizontal direction (X direction) from the bit line 270 to the capacitor structure 280. The first portion 212C of the first semiconductor pattern 212R may be surrounded by a gate structure 250, the second portion 212S of the first semiconductor pattern 212R may be surrounded by a third insulating layer 260 and connected to the bit line 270, and the third portion 212D of the first semiconductor pattern 212R may be surrounded by a first insulating layer 230 and a second insulating layer 240 and connected to a first electrode 282 of the capacitor structure 280. The second portion 212S of the first semiconductor pattern 212R may be surrounded by an insulating spacer 260SP, which is a portion of the third insulating layer 260.

For example, both side surfaces of the third portion 212D of the first semiconductor pattern 212R in the second horizontal direction (Y direction) may be covered by the first insulating layer 230, and upper and lower surfaces of the third portion 212D of the first semiconductor pattern 212R may be covered by the second insulating layer 240. The second portion 212S, the first portion 212C, and the third portion 212D of the first semiconductor pattern 212R may be referred to as a source region, a channel region, and a drain region, respectively. In the first horizontal direction (X direction), the first semiconductor pattern 212R may have a cell length LC. In the first horizontal direction (X direction), the first portion 212C of the first semiconductor pattern 212R may have a first length L1, the second portion 212S of the first semiconductor pattern 212R may have a second length L2, and the third portion 212D of the first semiconductor pattern 212R may have a third length L3. The cell length LC may be the sum of the first length L1, the second length L2, and the third length L3. The first length L1 may be greater than the second length L2 and the third length L3. In some embodiments, the third length L3 may be greater than the second length L2, but embodiments are not limited thereto. The first portion 212C and the second portion 212S of the first semiconductor pattern 212R may have a first horizontal width W1 in the second horizontal direction (Y direction). The third portion 212D of the first semiconductor pattern 212R may have a horizontal width that is greater than the first horizontal width W1 in the second horizontal direction (Y direction). In the vertical direction (Z direction), the third portion 212D of the first semiconductor pattern 212R may have a greater thickness than each of the first portion 212C and the second portion 212S of the first semiconductor pattern 212R. That is, the third portion 212D of the first semiconductor pattern 212R may be have a greater thickness in the vertical direction (Z direction) and a greater horizontal width in the second horizontal direction (Y direction) than each of the first portion 212C and the second portion 212S of the first semiconductor pattern 212R. In some embodiments, each of the first portion 212C and the second portion 212S of the first semiconductor pattern 212R may have substantially the same horizontal width in the second horizontal direction (Y direction). In some embodiments, each of the first portion 212C and the second portion 212S of the first semiconductor pattern 212R may have substantially the same thickness in the vertical direction (Z direction).

In the first horizontal direction (X direction), the second semiconductor pattern 214D may have a dummy length LD. The dummy length LD may be less than the cell length LC. A portion of the second semiconductor pattern 214D may be surrounded by the gate structure 250, and another portion of the second semiconductor pattern 214D may be surrounded by the insulating spacer 260SP. In the first horizontal direction (X direction), the portion of the second semiconductor pattern 214D that is surrounded by the gate structure 250 may have a fourth length L4, and the portion of the second semiconductor pattern 214D that is surrounded by the insulating spacer 260SP may have a fifth length L5. The fourth length L4 may be less than the first length L1. The fifth length L5 may be substantially equal to the second length L2. The portion of the second semiconductor pattern 214D that is surrounded by the gate structure 250 and has the fourth length L4 in the first horizontal direction (X direction) may be referred to as a first dummy portion, the portion of the second semiconductor pattern 214D that is surrounded by the insulating spacer 260SP and has the fifth length L5 in the first horizontal direction (X direction) may be referred to as a second dummy portion, and the second semiconductor pattern 214D may have a second horizontal width W2 in the second horizontal direction (Y direction). In some embodiments, the second semiconductor pattern 214D may extend from an end to the other end thereof in the first horizontal direction (X direction), and may have substantially the same horizontal width in the second horizontal direction (Y direction) and substantially the same thickness in the vertical direction (Z direction). For example, in the vertical direction (Z direction), the thickness of the second semiconductor pattern 214D may be substantially the same as the thickness of each of the first portion 212C and the second portion 212S of the first semiconductor pattern 212R. The second horizontal width W2 may be less than the first horizontal width W1. For example, the first horizontal width W1 may have a value that is at least twice that of the second horizontal width W2. The first semiconductor pattern 212R and the second semiconductor pattern 214D adjacent to one another in the second horizontal direction (Y direction) may be spaced apart from one another by a pattern interval ITY. The pattern interval ITY may be less than the first horizontal width W1 and greater than the second horizontal width W2.

In the first horizontal direction (X direction), an end of the first semiconductor pattern 212R may be in contact with the bit line 270, and an end of the second semiconductor pattern 214D may be in contact with the third insulating layer 260. The second semiconductor pattern 214D may be electrically insulated from the bit line 270 by being spaced apart from the bit line 270 with the third insulating layer 260 therebetween. In the first horizontal direction (X direction), the other end of the first semiconductor pattern 212R may be in contact with the first electrode 282 of the capacitor structure 280, and the other end of the second semiconductor pattern 214D may be in contact with the first insulating layer 230. The second semiconductor pattern 214D may be electrically insulated from the capacitor structure 280 by being spaced apart from the capacitor structure 280 with the first insulating layer 230 therebetween. In the first horizontal direction (X direction), an end of the first semiconductor pattern 212R may be aligned with an end of the second semiconductor pattern 214D in the second horizontal direction (Y direction). In the first horizontal direction (X direction), the other end of the first semiconductor pattern 212R may not be aligned with the other end of the second semiconductor pattern 214D in the second horizontal direction (Y direction).

The first insulating layer 230 may fill a space between the third portions 212D of the first semiconductor patterns 212R adjacent to one another in the second horizontal direction (Y direction), and may cover ends of the second semiconductor patterns 214D in the first horizontal direction (X direction) toward a capacitor trench CTR. In some embodiments, the first insulating layer 230 may further cover both side surfaces in the second horizontal direction (Y direction) of portions of the ends of the second semiconductor patterns 214D in the first horizontal direction (X direction) toward the capacitor trench CTR. The first insulating layer 230 may cover ends of the second semiconductor patterns 214D aligned in the vertical direction (Z direction), and may extend in the vertical direction (Z direction) to form a single body. The second insulating layer 240 may fill a space between the first semiconductor patterns 212R adjacent to one another in the vertical direction (Z direction) and a space between the second semiconductor patterns 214D adjacent to one another in the vertical direction (Z direction). The first insulating layer 230 and the second insulating layer 240 may be collectively referred to as an interlayer insulating layer. The interlayer insulating layer may surround the plurality of first semiconductor patterns 212R, the plurality of second semiconductor patterns 214D, and the plurality of gate structures 250.

The gate structure 250 may include a gate dielectric layer 252 and a gate electrode 254. The gate dielectric layer 252 may conformally cover a surface of each of the first insulating layer 230, the second insulating layer 240, the first semiconductor pattern 212R, and the second semiconductor pattern 214D, located in a space excluding a gate recess 250RS in a second removal space 210RS. The gate electrode 254 may surround the first semiconductor pattern 212R and the second semiconductor pattern 214D with the gate dielectric layer 252 therebetween. The gate electrode 254 may extend in the second horizontal direction (Y direction), and may cover upper and lower surfaces and both side surfaces in the second horizontal direction (Y direction) of each of the first semiconductor pattern 212R and the second semiconductor pattern 214D. For example, the gate electrode 254 may have a gate-all-around (GAA) structure that completely surrounds the first semiconductor pattern 212R in a vertical cross-section (Y-Z vertical cross-section) formed by the second horizontal direction (Y direction) and the vertical direction (Z direction). The gate electrode 254 may be spaced apart from the bit line 270 with the third insulating layer 260 including the insulating spacer 260SP therebetween.

The third insulating layer 260 may surround the plurality of bit lines 270, and may fill a line trench LTR. The plurality of bit lines 270 may fill a plurality of bit line holes 270H penetrating the third insulating layer 260. The plurality of bit lines 270 may be connected to ends of the plurality of first semiconductor patterns 212R in the first horizontal direction (X direction). The third insulating layer 260 may further fill a plurality of gate recesses 250RS, which are portions of the plurality of second removal spaces 210RS. Each of the plurality of insulating spacers 260SP, which are portions of the third insulating layer 260 that fill the plurality of gate recesses 250RS, may surround the second portion 212S of the first semiconductor pattern 212R or a portion of the second semiconductor pattern 214D that is adjacent to the line trench LTR.

The plurality of capacitor structures 280 may include a plurality of first electrodes 282, a capacitor dielectric layer 284, and a second electrode 286. The plurality of capacitor structures 280 may be connected to the other ends of the plurality of first semiconductor patterns 212R in the first horizontal direction (X direction). The plurality of first electrodes 282 may be formed on the other ends of the plurality of first semiconductor patterns 212R in the first horizontal direction (X direction), the capacitor dielectric layer 284 may cover the plurality of first electrodes 282, and the second electrode 286 may cover the plurality of first electrodes 282 with the capacitor dielectric layer 284 therebetween. The capacitor dielectric layer 284 may be formed to conformally cover the plurality of first electrodes 282. In some embodiments, the capacitor dielectric layer 284 may be formed as a single body within the capacitor trench CTR to conformally cover the plurality of first electrodes 282, the plurality of first insulating layers 230, and the second insulating layer 240. In some embodiments, the second electrode 286 may be formed as a single body within the capacitor trench CTR to conformally cover the plurality of first electrodes 282, the plurality of first insulating layers 230, and the second insulating layer 240 with the capacitor dielectric layer 284 therebetween. The second electrode 286 may be connected to the ground wiring PP shown in FIG. 1, or may be a portion of the ground wiring PP. A fourth insulating layer 290 may cover the plurality of capacitor structures 280, and may fill the capacitor trench CTR.

The third insulating layer 260 may be referred to as a line trench filling insulating layer or a first filling insulating layer, and the fourth insulating layer 290 may be referred to as a capacitor trench filling insulating layer or a second filling insulating layer.

In the semiconductor memory device 1 according to the disclosed concepts, because the second semiconductor pattern 214D is arranged between the first semiconductor patterns 212R adjacent to one another in the second horizontal direction (Y direction), voids may be prevented from occurring within the gate electrode 254 included in the gate structure 250. Accordingly, the gate electrode 254 may be prevented from becoming thin or broken due to voids, and thus, the operational reliability of the semiconductor memory device 1 may be improved.

In some embodiments, the semiconductor memory device 1 shown in FIGS. 3A, 3B, 3C, and 3D may be stacked with a peripheral circuit structure to form a semiconductor apparatus. For example, the semiconductor apparatus may have a cell-on-periphery (CoP) structure or a periphery-on-cell (PoC) structure in which the peripheral circuit structure is formed below or above the semiconductor memory device 1 shown in FIGS. 3A, 3B, 3C, and 3D or is bonded thereto. The peripheral circuit structure may include a peripheral circuit board and a plurality of peripheral circuit transistors. The plurality of peripheral circuit transistors may be configured to transmit signals and/or power to a plurality of memory cells included in the semiconductor memory device 1 shown in FIGS. 3A, 3B, 3C, and 3D. For example, the plurality of peripheral circuit transistors may form various circuits, such as a command decoder, a control logic, an address buffer, a row decoder, a column decoder, a sense amplifier, and a data input/output circuit. Each of the plurality of peripheral circuit transistors may be a planar transistor, a fin field-effect transistor (FinFET), and/or a vertical gate transistor.

In some embodiments, the peripheral circuit structure and the semiconductor memory device 1 shown in FIGS. 3A, 3B, 3C, and 3D may be bonded to one another using a hybrid bonding method. For example, the peripheral circuit structure may include a peripheral circuit bonding pad and a peripheral circuit bonding insulating layer surrounding the peripheral circuit bonding pad, and the semiconductor memory device 1 shown in FIGS. 3A, 3B, 3C, and 3D may include a cell bonding pad and a cell bonding insulating layer surrounding the cell bonding pad. The cell bonding insulating layer and the peripheral circuit bonding insulating layer may be bonded to one another by covalent bonding, the cell bonding pad and the peripheral circuit bonding pad may face one another and expand due to heat to come into contact with one another, and the cell bonding pad and the peripheral circuit bonding pad may be bonded to one another by diffusion bonding to form a single body through diffusion of metal atoms included therein. The cell bonding pad and the peripheral circuit bonding pad may include a material including copper (Cu). The cell bonding insulating layer and the peripheral circuit bonding insulating layer may include silicon oxide or silicon carbonitride (SiCN).

In some embodiments, the peripheral circuit structure and the semiconductor memory device 1 shown in FIGS. 3A, 3B, 3C, and 3D may be bonded to one another using a direct bonding method. For example, the peripheral circuit structure may include a peripheral circuit bonding insulating layer, and the semiconductor memory device 1 shown in FIGS. 3A, 3B, 3C, and 3D may include a cell bonding insulating layer. The cell bonding insulating layer and the peripheral circuit bonding insulating layer may be bonded to one another by covalent bonding, and the peripheral circuit structure and the semiconductor memory device 1 shown in FIGS. 3A, 3B, 3C, and 3D may be electrically connected to one another by a plurality of through vias penetrating the cell bonding insulating layer and the peripheral circuit bonding insulating layer.

In some embodiments, the plurality of first semiconductor patterns 212R, the plurality of second semiconductor patterns 214D, the plurality of gate dielectric layers 252, the plurality of gate electrodes 254, the plurality of bit lines 270, and the plurality of capacitor structures 280 included in the semiconductor memory device 1 may be arranged on a base substrate. The base substrate may include, for example, silicon (Si), such as crystalline Si, polycrystalline Si, or amorphous Si. Alternatively, the base substrate may include a semiconductor element, such as germanium (Ge), or at least one compound semiconductor selected from silicon germanium (SiGe), silicon carbide (SiC), gallium arsenide (GaAs), indium arsenide (InAs), and indium phosphide (InP). Alternatively, the base substrate may include a silicon-on-insulator (SOI) substrate or a germanium-on-insulator (GeOI) substrate. For example, the base substrate may include a buried oxide (BOX) layer. The base substrate may include a conductive region, for example, an impurity-Attorney doped well or an impurity-doped structure. A plurality of peripheral circuit transistors may be arranged on the base substrate.

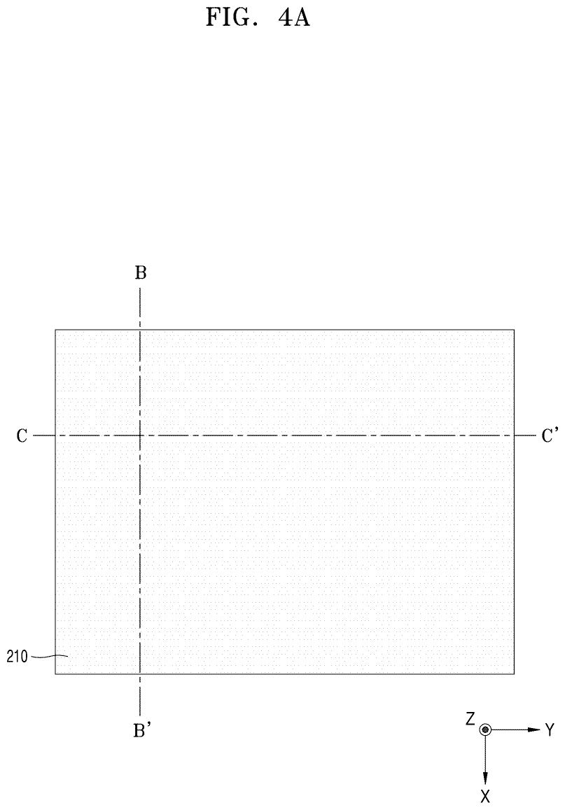

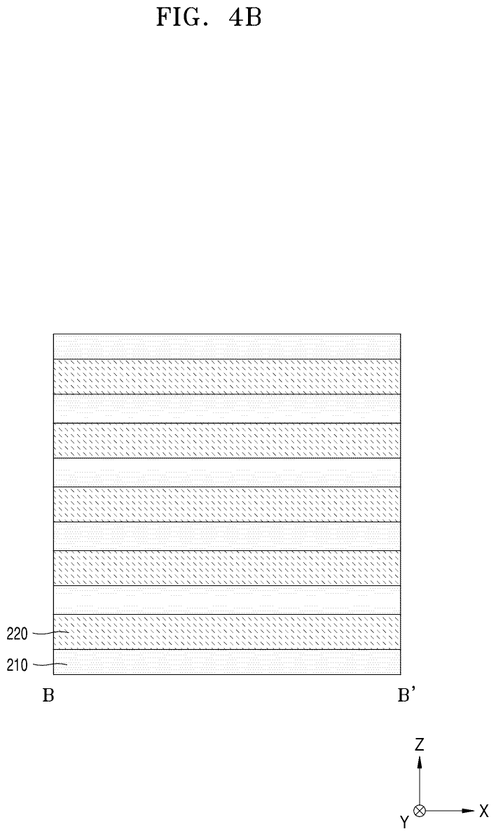

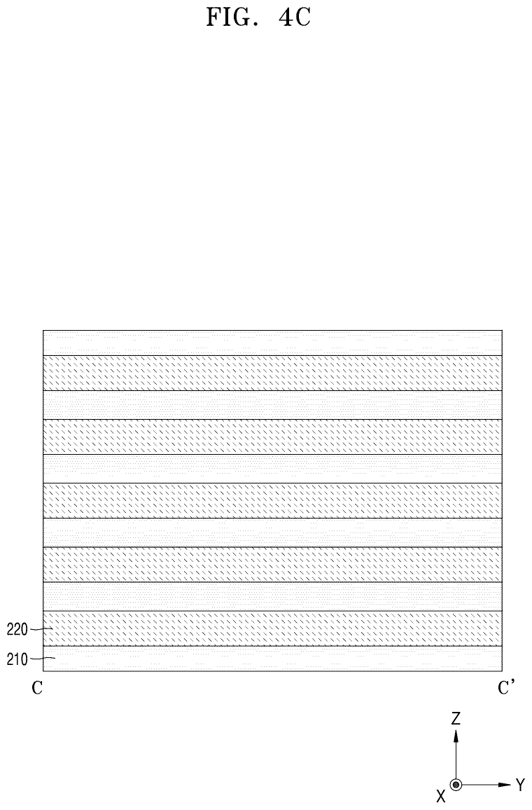

FIGS. 4A, 4B, 4C, 5A, 5B, 5C, 6A, 6B, 6C, 7A, 7B, 7C, 8A, 8B, 8C, 9A, 9B, 9C, 10A, 10B, 10C, 11A, 11B, 11C, 12A, 12B, 12C, 13A, 13B, 13C, 14A, 14B, 14C, 15A, 15B, 15C, and 16A, 16B, and 16C are diagrams illustrating a method of manufacturing a semiconductor memory device, according to embodiments. In detail, FIGS. 4A, 5A, 6A, 7A, 8A, 9A, 10A, 11A, 12A, 13A, 14A, 15A, and 16A are plan layout views illustrating the method of manufacturing a semiconductor memory device, FIGS. 4B, 5B, 6B, 7B, 8B, 9B, 10B, 11B, 12B, 13B, 14B, 15B, and 16B are cross-sectional views taken along lines B-B′ of FIGS. 4A, 5A, 6A, 7A, 8A, 9A, 10A, 11A, 12A, 13A, 14A, 15A, and 16A, and FIGS. 4C, 5C, 6C, 7C, 8C, 9C, 10C, 11C, 12C, 13C, 14C, 15C, and 16C are cross-sectional views taken along lines C-C′ of FIGS. 4A, 5A, 6A, 7A, 8A, 9A, 10A, 11A, 12A, 13A, 14A, 15A, and 16A.

Referring to FIGS. 4A, 4B, and 4C, a plurality of semiconductor layers 210 and a plurality of sacrificial layers 220 are alternately formed in the vertical direction (Z direction) to form a stacked structure. Each of the plurality of semiconductor layers 210 and the plurality of sacrificial layers 220 may include a semiconductor material. The sacrificial layer 220 may include a semiconductor material having etch selectivity with respect to the semiconductor layer 210. For example, the semiconductor layer 210 may include Si, and the sacrificial layer 220 may include SiGe or SiGeC. In some embodiments, the semiconductor layer 210 may include a 2D semiconductor material or an oxide semiconductor material.

In some embodiments, the plurality of semiconductor layers 210 and the plurality of sacrificial layers 220 may be formed on a support substrate. The support substrate may be a semiconductor substrate, a ceramic substrate, or a glass substrate.

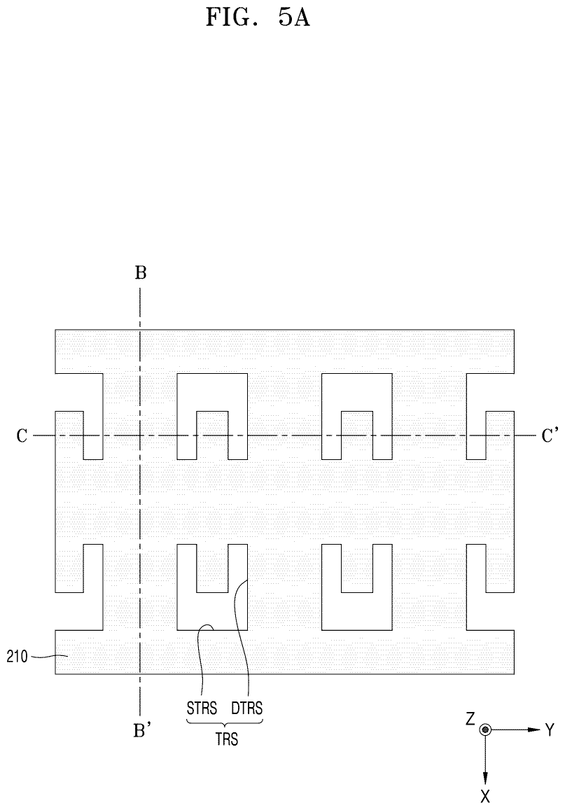

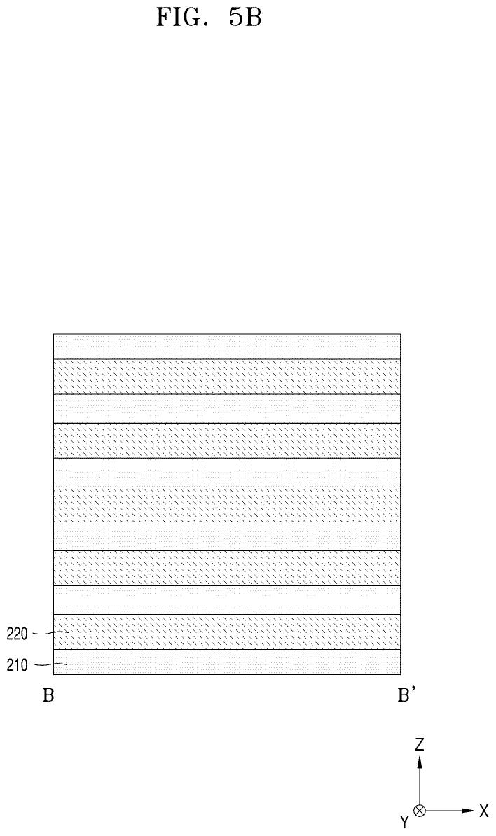

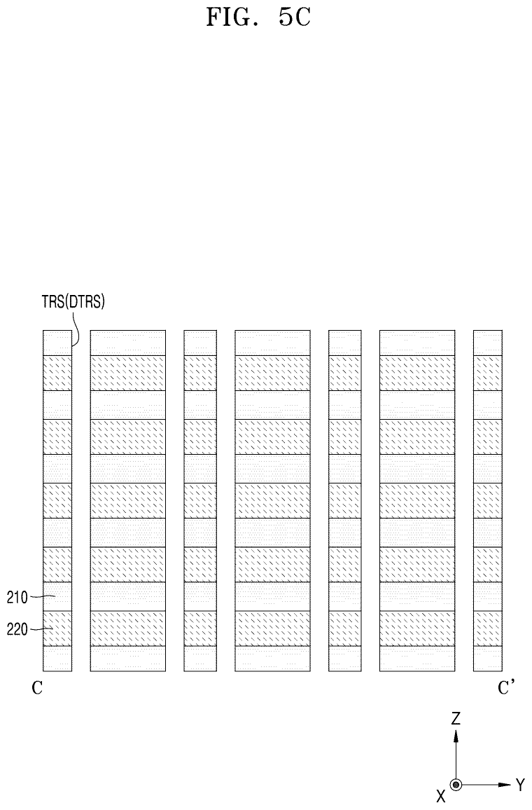

Referring to FIGS. 5A, 5B, and 5C, a plurality of trim spaces TRS are formed to penetrate the plurality of semiconductor layers 210 and the plurality of sacrificial layers 220 and be spaced apart from one another in a plan view. The plurality of trim spaces TRS may be arranged spaced apart from one another in each of the first horizontal direction (X direction) and the second horizontal direction (Y direction). The trim spaces TRS arranged in the second horizontal direction (Y direction) may have the same planar shape. A pair of trim spaces TRS adjacent to one another in the first horizontal direction (X direction) may have planar shapes that are mirror symmetrical to one another.

For example, the trim space TRS may have a U-shape in a plan view. The trim space TRS may include a pair of separate trim spaces DTRS that extend in the first horizontal direction (X direction) and are spaced apart from one another in the second horizontal direction (Y direction), and a short-axis trim space STRS connecting ends of the pair of separate trim spaces DTRS to one another in the second horizontal direction (Y direction).

The horizontal width in the second horizontal direction (Y direction) of a portion of the semiconductor layer 210 that is located between the pair of separate trim spaces DTRS of one trim space TRS may be less than the horizontal width in the second horizontal direction (Y direction) of a portion of the semiconductor layer 210 that is located between a pair of trim spaces TRS adjacent to one another in the second horizontal direction (Y direction). For example, among the separate trim spaces DTRS arranged in the second horizontal direction (Y direction), a gap between a pair of separate trim spaces DTRS that are adjacent to one another in the second horizontal direction (Y direction) and connected to one another by the short-axis trim space STRS may be less than a gap between a pair of separate trim spaces DTRS that are adjacent to one another in the second horizontal direction (Y direction) and not connected to one another by the short-axis trim space STRS. The horizontal width in the first horizontal direction (X direction) of a portion of the semiconductor layer 210 that is located between the pair of separate trim spaces DTRS of one trim space TRS may be less than the horizontal width in the first horizontal direction (X direction) of a portion of the semiconductor layer 210 that is located between a pair of trim spaces TRS adjacent to one another in the second horizontal direction (Y direction). For example, the horizontal width in the first horizontal direction (X direction) of the portion of the semiconductor layer 210 that is located between the pair of separate trim spaces DTRS of one trim space TRS may be less than the horizontal width in the first horizontal direction (X direction) of the portion of the semiconductor layer 210 that is located between the pair of trim spaces TRS adjacent to one another in the second horizontal direction (Y direction) by the horizontal width in the first horizontal direction (X direction) of the short-axis trim space STRS.

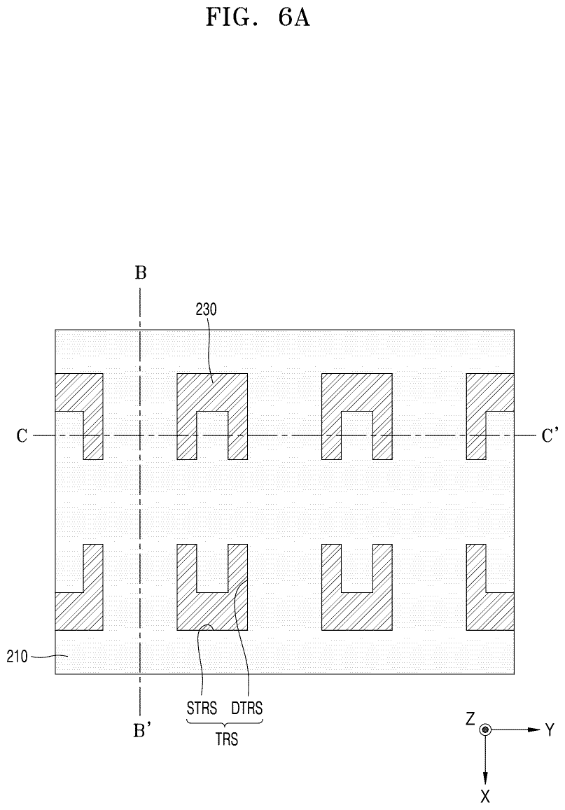

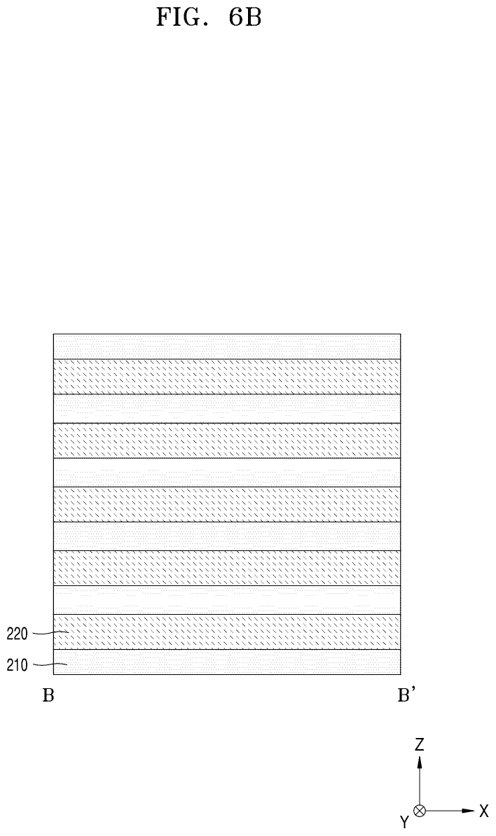

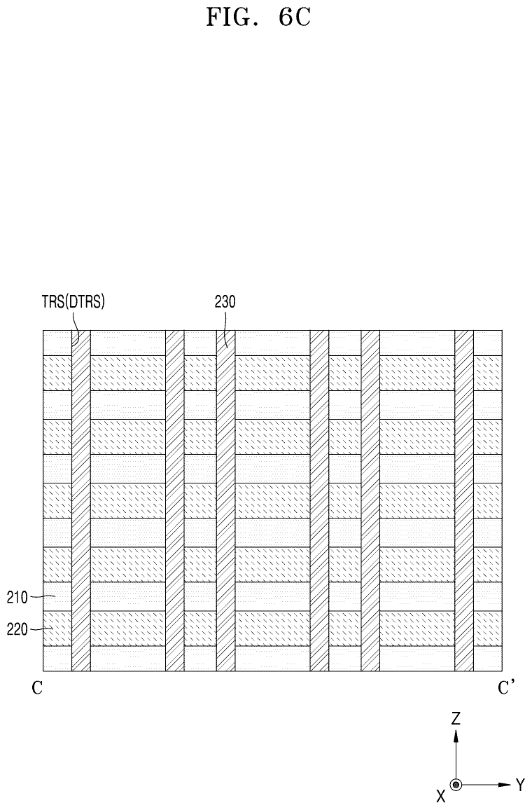

Referring to FIGS. 6A, 6B, and 6C, a plurality of first insulating layers 230 are formed to fill the plurality of trim spaces TRS. The first insulating layer 230 may include oxide, nitride, oxynitride, carbonitride, or a combination thereof. Corresponding to the trim space TRS, the first insulating layer 230 may have a U-shape in a plan view.

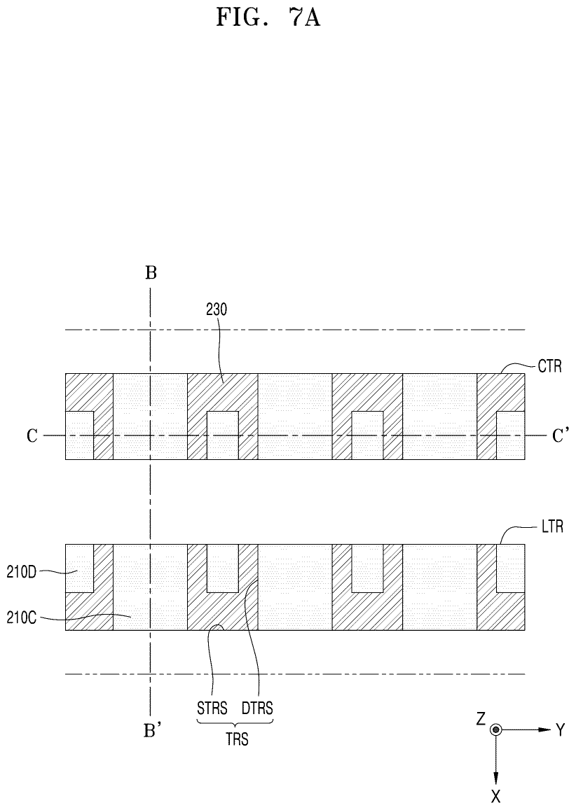

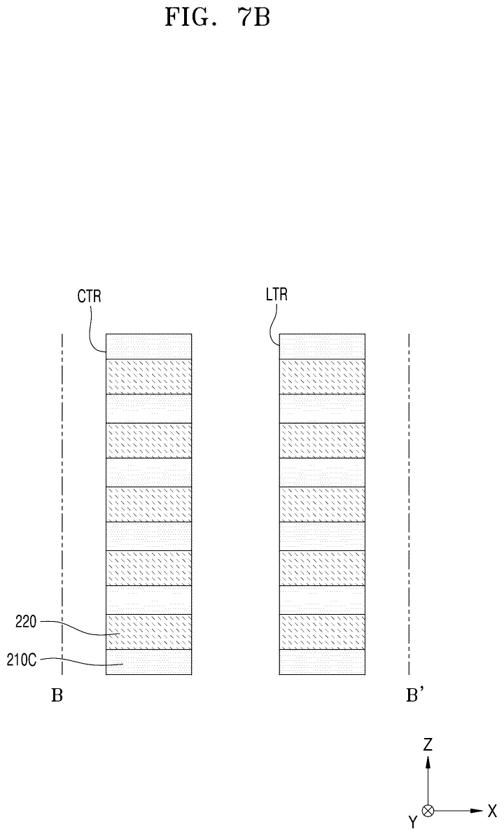

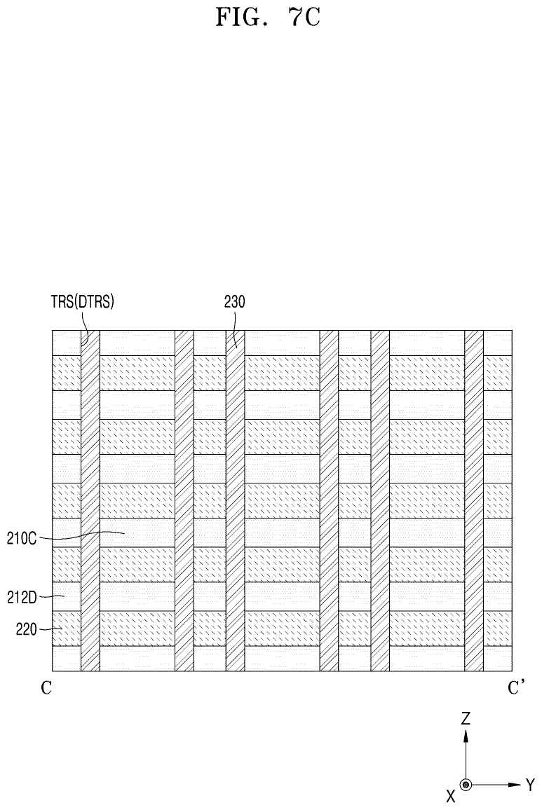

Referring to FIGS. 6A, 6B, 6C, 7A, 7B, and 7C, a line trench LTR and a capacitor trench CTR are formed to extend in the second horizontal direction (Y direction) between the trim spaces TRS adjacent to one another in the first horizontal direction (X direction) and penetrate the plurality of semiconductor layers 210 and the plurality of sacrificial layers 220. The line trench LTR and the capacitor trench CTR may be formed alternately in the first horizontal direction (X direction). The first insulating layers 230 filling the trim spaces TRS may be exposed on an inner side surface of each of the line trench LTR and the capacitor trench CTR. The capacitor trench CTR may be formed on the side of the short-axis trim space STRS connecting ends of the pair of separate trim spaces DTRS of each of the plurality of trim spaces TRS to one another in the first horizontal direction (X direction), and the line trench LTR may be formed on the side of the other ends of the pair of separate trim spaces DTRS of each of the plurality of trim spaces TRS in the first horizontal direction (X direction). For example, portions of the first insulating layer 230 that fill the separate trim spaces DTRS may be exposed on the inner side surface of the line trench LTR, and portions of the first insulating layer 230 that fill the short-axis trim spaces STRS may be exposed on the inner side surface of the capacitor trench CTR.

By the line trench LTR and the capacitor trench CTR, the plurality of semiconductor layers 210 may be separated into a plurality of first semiconductor layers 210C and a plurality of second semiconductor layers 210D. For example, the first semiconductor layers 210C may be arranged between a pair of trim spaces TRS adjacent to one another in the second horizontal direction (Y direction), and the second semiconductor layers 210D may be arranged between the pair of separate trim spaces DTRS and the short-axis trim space STRS included in one trim space TRS.

A portion of the first insulating layer 230 may be provided between the first semiconductor layer 210C and the second semiconductor layer 210D adjacent to one another in the second horizontal direction (Y direction). The plurality of first insulating layers 230 may cover both side walls of the plurality of first semiconductor layers 210C in the second horizontal direction (Y direction). The plurality of first insulating layers 230 may cover both side walls of the plurality of second semiconductor layers 210D in the second horizontal direction (Y direction) and a side wall of the plurality of second semiconductor layers 210D in the first horizontal direction (X direction) toward the capacitor trench CTR. A side wall of the plurality of first semiconductor layers 210C in the first horizontal direction (X direction) may be exposed in the capacitor trench CTR, and the other side wall of the plurality of first semiconductor layers 210C in the first horizontal direction (X direction) may be exposed in the line trench LTR. A side wall of the plurality of second semiconductor layers 210D in the first horizontal direction (X direction) toward the capacitor trench CTR may be covered by a portion of the first insulating layer 230, and the other side wall of the plurality of second semiconductor layers 210D in the first horizontal direction (X direction) may be exposed in the line trench LTR.

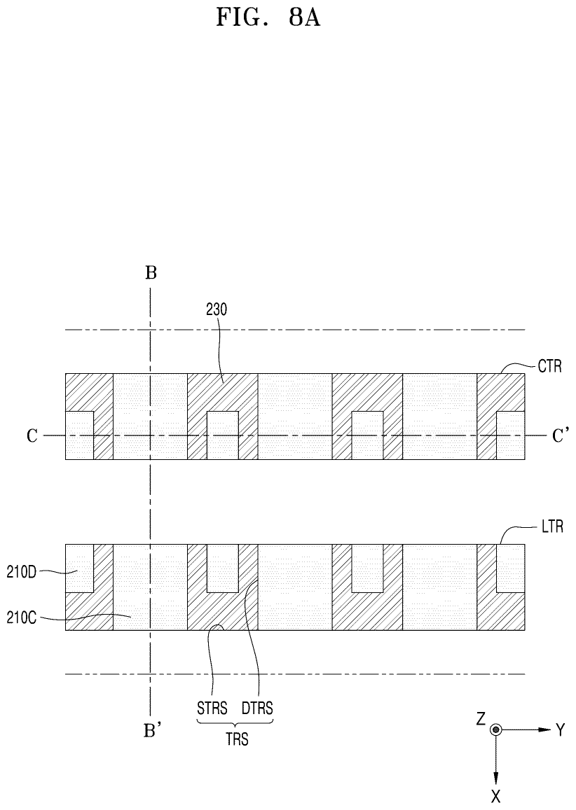

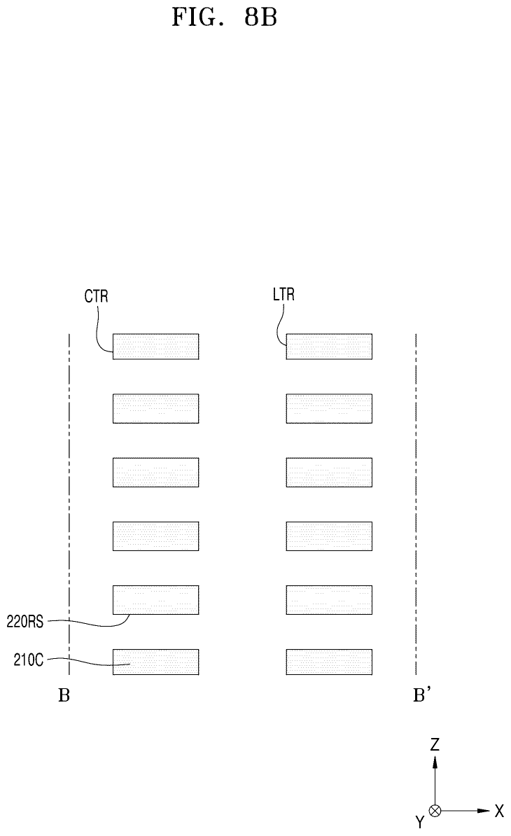

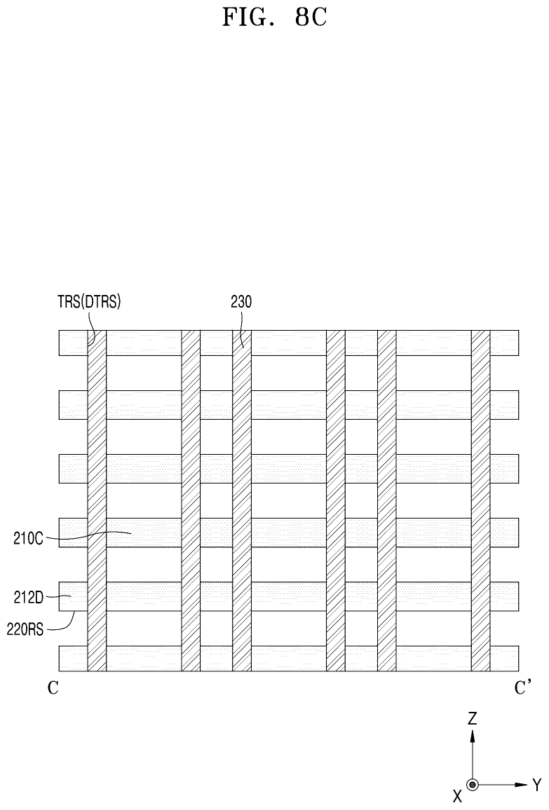

Referring to FIGS. 7A, 7B, 7C, 8A, 8B, and 8C, the plurality of sacrificial layers 220 are removed to form a plurality of first removal spaces 220RS. The plurality of first removal spaces 220RS may be connected to each of the line trench LTR and the capacitor trench CTR. The plurality of first removal spaces 220RS may be formed between the first semiconductor layers 210C adjacent to one another in the vertical direction (Z direction) and between the second semiconductor layers 210D adjacent to one another in the vertical direction (Z direction).

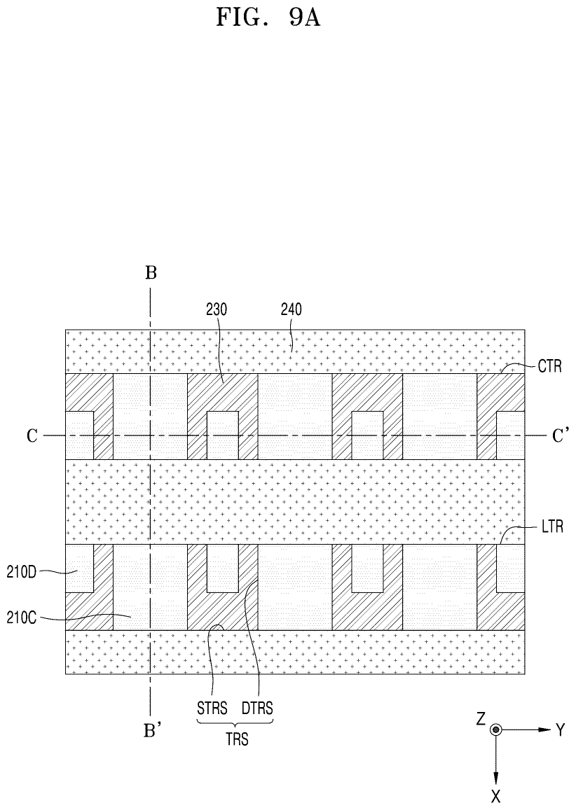

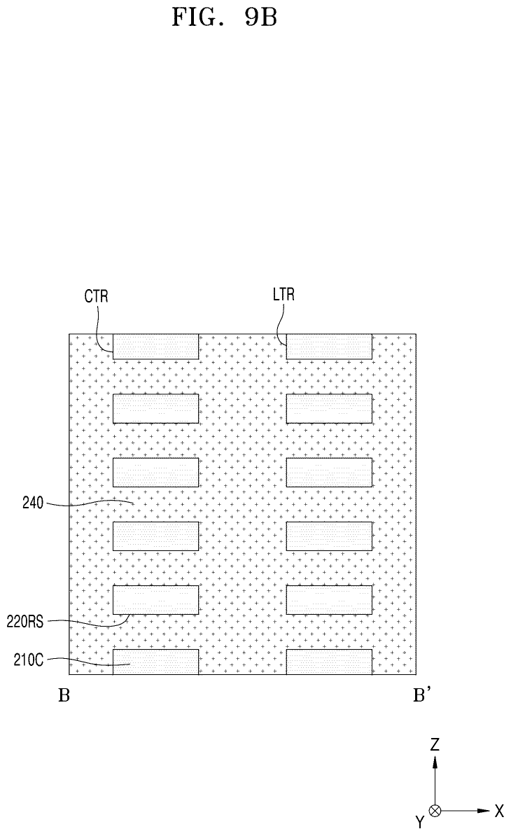

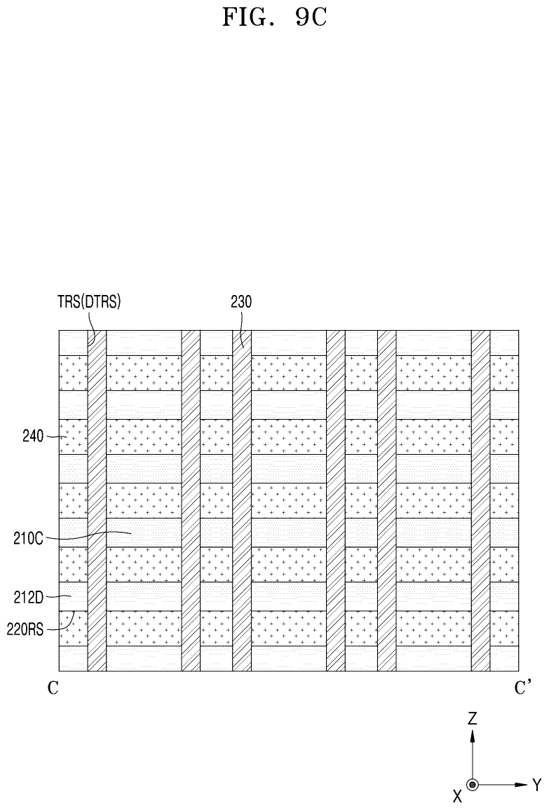

Referring to FIGS. 9A, 9B, and 9C, a second insulating layer 240 is formed to fill the line trench LTR, the capacitor trench CTR, and the plurality of first removal spaces 220RS. The second insulating layer 240 may include oxide, nitride, oxynitride, carbonitride, or a combination thereof. In some embodiments, the second insulating layer 240 may include the same material as the first insulating layer 230, but embodiments are not limited thereto. For example, the second insulating layer 240 may include an insulating material having etch selectivity with respect to the first insulating layer 230.

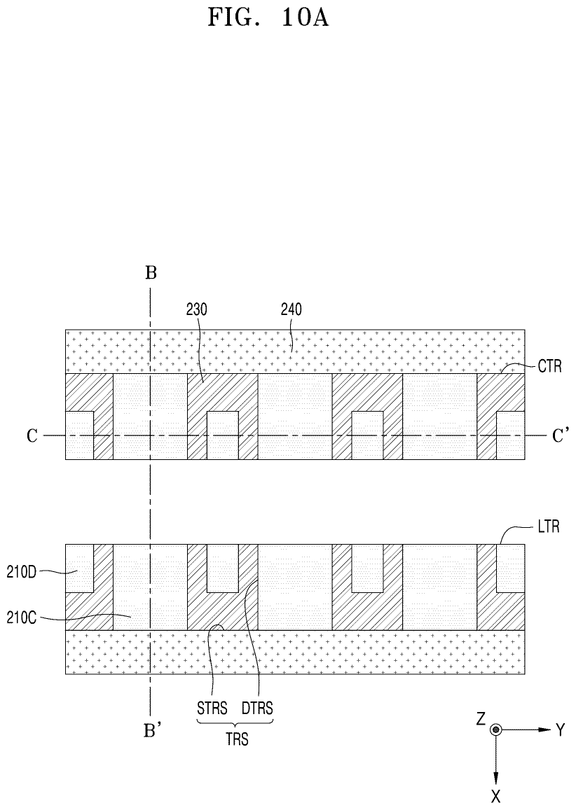

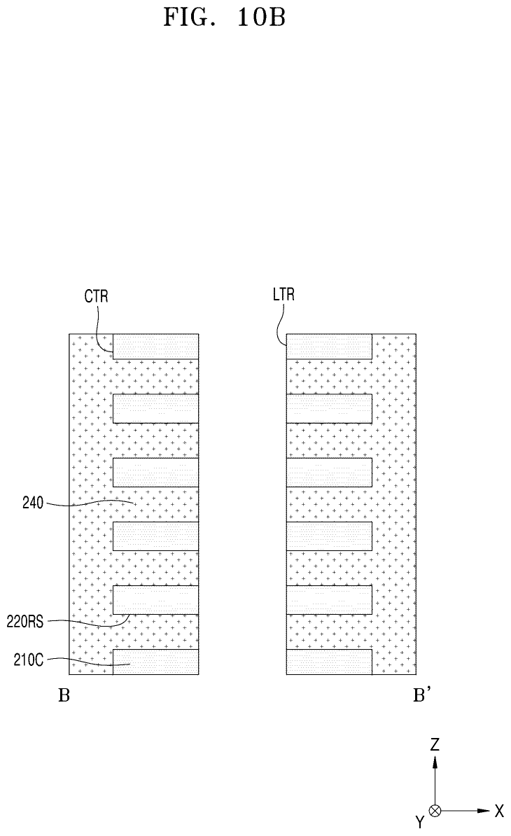

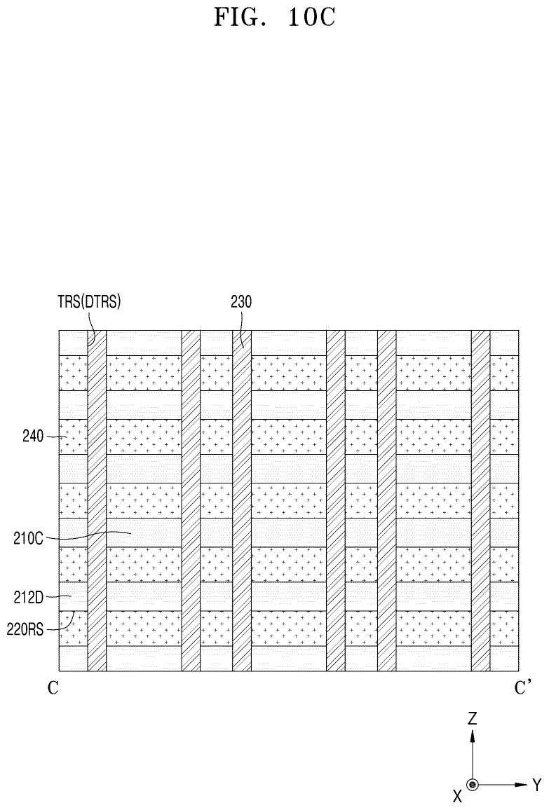

Referring to FIGS. 10A, 10B, and 10C, a portion of the second insulating layer 240 that fills the line trench LTR is removed to expose the plurality of first semiconductor layers 210C, the plurality of second semiconductor layers 210D, and the plurality of first insulating layers 230 on the inner side wall of the line trench LTR.

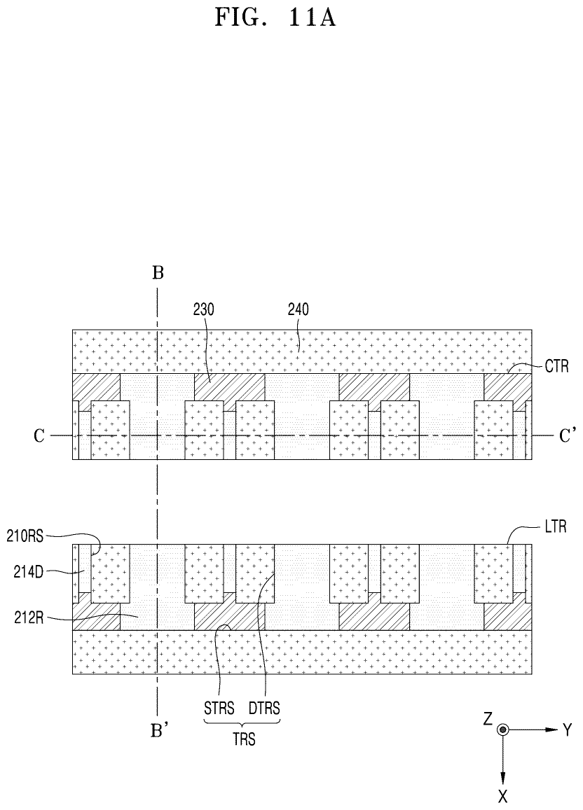

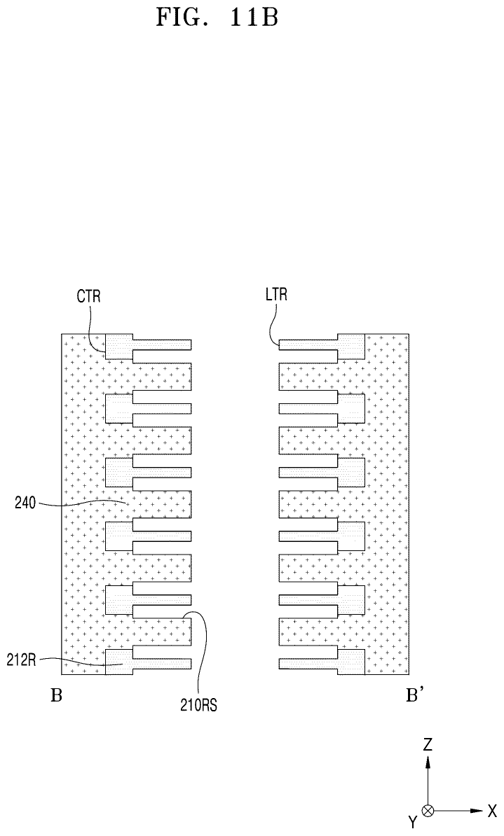

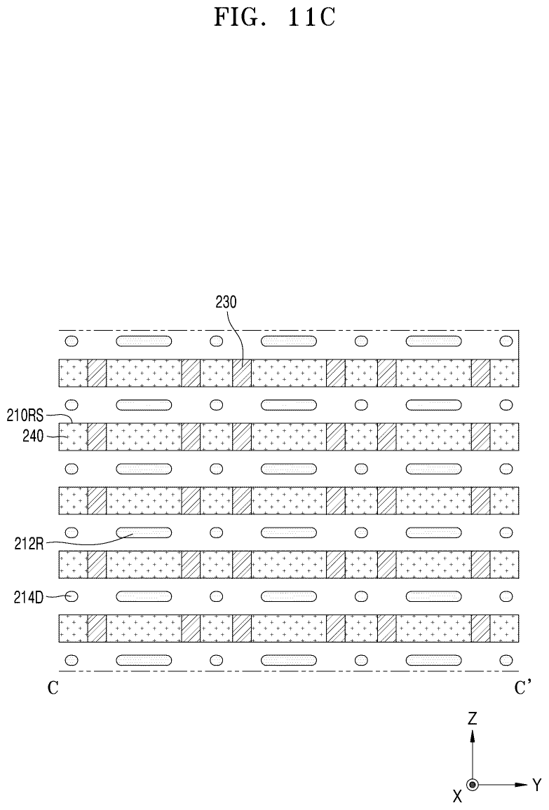

Referring to FIGS. 10A, 10B, 10C, 11A, 11B, and 11C, a portion of each of the plurality of first semiconductor layers 210C and the plurality of second semiconductor layers 210D is removed through the line trench LTR to form a plurality of first semiconductor patterns 212R and a plurality of second semiconductor patterns 214D.

In some embodiments, in the process of removing a portion of each of the plurality of first semiconductor layers 210C and the plurality of second semiconductor layers 210D, portions of the plurality of first insulating layers 230 may also be removed. For example, in the process of removing a portion of each of the plurality of first semiconductor layers 210C and the plurality of second semiconductor layers 210D, a portion of the first insulating layer 230 that is arranged between the first semiconductor layer 210C and the second semiconductor layer 210D in the second horizontal direction (Y direction) may also be removed.

In some embodiments, in the process of removing a portion of each of the plurality of first semiconductor layers 210C and the plurality of second semiconductor layers 210D, portions of the second insulating layer 240 may also be removed. For example, in the process of removing a portion of each of the plurality of first semiconductor layers 210C and the plurality of second semiconductor layers 210D, portions of the second insulating layer 240 that are adjacent to the plurality of first semiconductor layers 210C and the plurality of second semiconductor layers 210D in the vertical direction (Z direction) may also be removed.

A plurality of second removal spaces 210RS may be defined in spaces where portions of the plurality of first semiconductor layers 210C and portions of the plurality of second semiconductor layers 210D have been removed. In some embodiments, the plurality of second removal spaces 210RS may further include spaces where portions of the plurality of first insulating layers 230 and/or portions of the second insulating layer 240 have been removed. In some embodiments, the horizontal width of the second removal space 210RS in the first horizontal direction (X direction) may be less than the horizontal width of the first semiconductor pattern 212R in the first horizontal direction (X direction) and greater than the horizontal width of the second semiconductor pattern 214D in the first horizontal direction (X direction).

The second semiconductor pattern 214D may be formed to have a reduced horizontal width in the second horizontal direction (Y direction) and a reduced thickness in the vertical direction (Z direction), compared to the second semiconductor layer 210D corresponding thereto. In the first horizontal direction (X direction), the second semiconductor pattern 214D may have a horizontal width in the second horizontal direction (Y direction) and a thickness in the vertical direction (Z direction) that are substantially the same. At least a portion of the first semiconductor pattern 212R may be formed to have a reduced horizontal width in the second horizontal direction (Y direction) and a reduced thickness in the vertical direction (Z direction), compared to at least a portion of the first semiconductor layer 210C corresponding thereto. In some embodiments, a portion of the first semiconductor pattern 212R may have a horizontal width in the second horizontal direction (Y direction) and a thickness in the vertical direction (Z direction) that are substantially the same as those of a portion of the first semiconductor layer 210C corresponding thereto. For example, a portion of the first semiconductor pattern 212R that is adjacent to the capacitor trench CTR in the first horizontal direction (X direction) may have a greater horizontal width in the second horizontal direction (Y direction) and a greater thickness in the vertical direction (Z direction) than a portion of the first semiconductor pattern 212R that is adjacent to the line trench LTR.

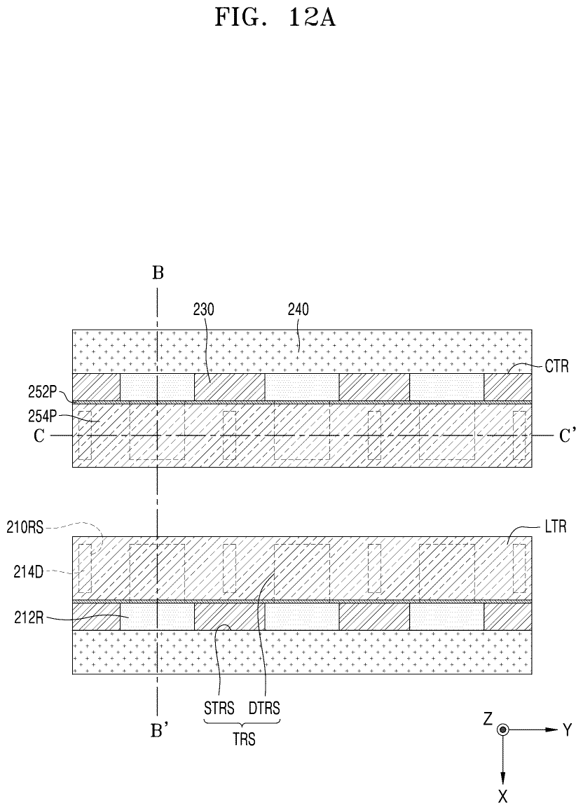

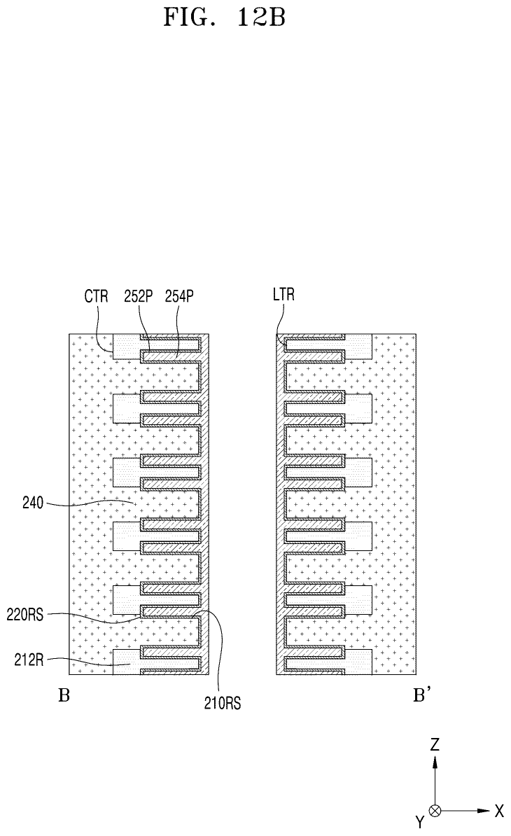

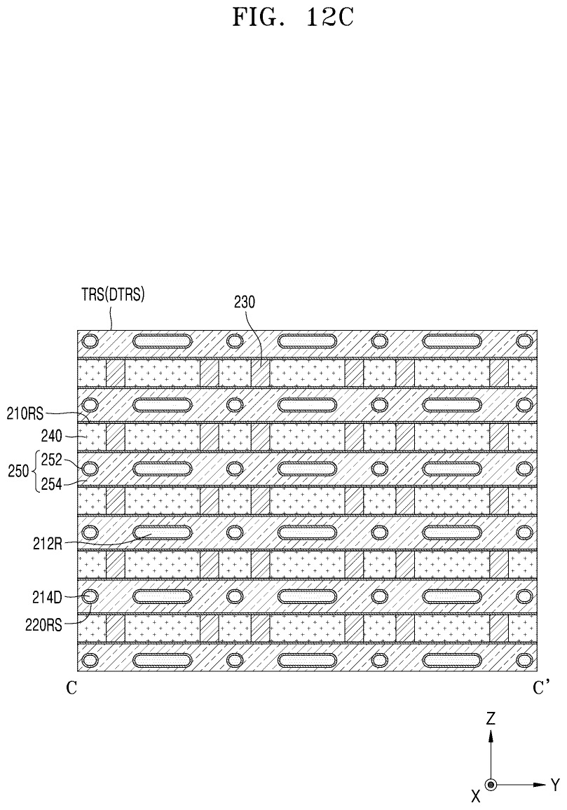

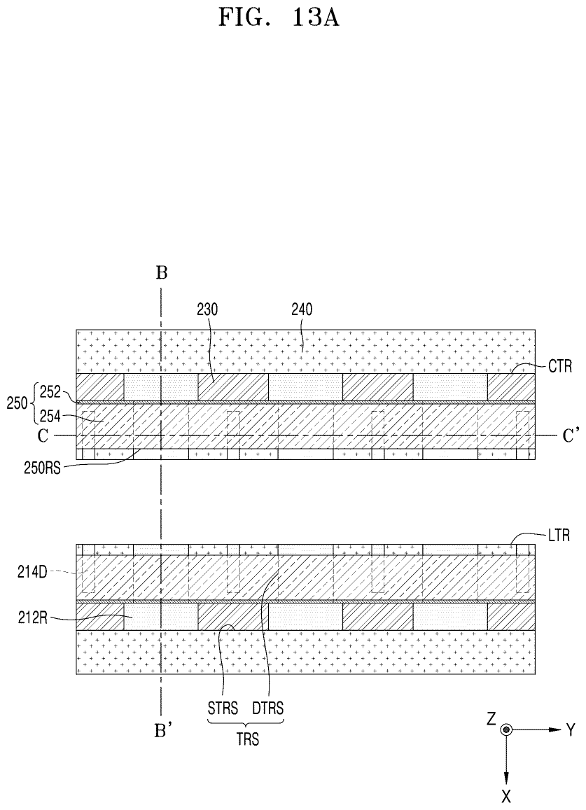

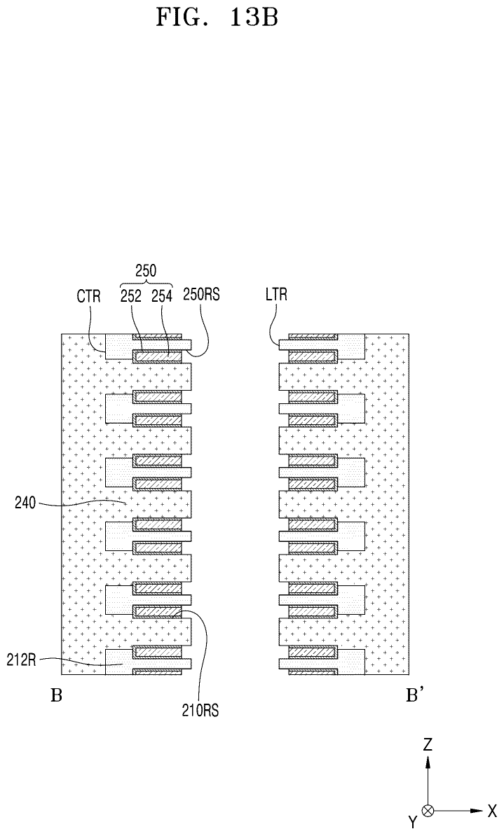

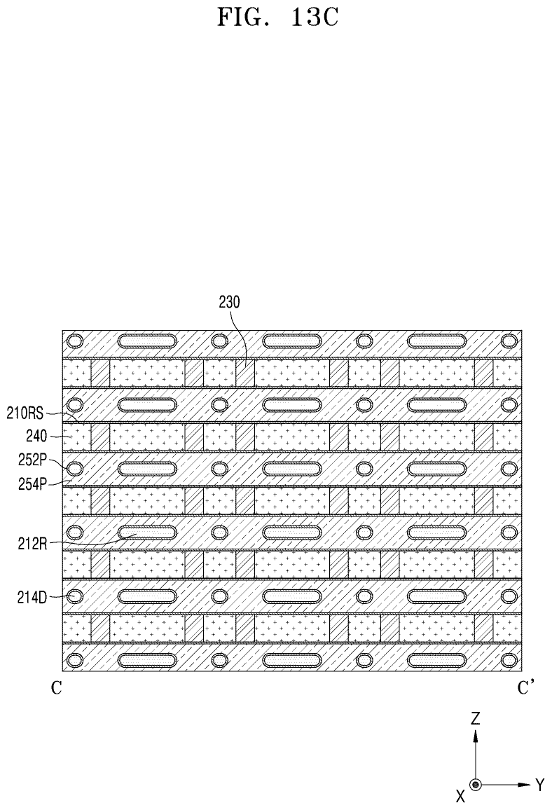

Referring to FIGS. 12A, 12B, and 12C, a preliminary dielectric layer 252P is formed to conformally to cover surfaces exposed within the plurality of second removal spaces 210RS and the line trench LTR, and then a preliminary electrode layer 254P is formed to cover the preliminary dielectric layer 252P and fill the plurality of second removal spaces 210RS and at least a portion of the line trench LTR. Referring to FIGS. 12A, 12B, 12C, 13A, 13B, and 13C, a portion of the preliminary dielectric layer 252P and a portion of the preliminary electrode layer 254P filling the line trench LTR and portions of the plurality of second removal spaces 210R are removed to form a plurality of gate structures 250 filling remaining portions of the plurality of second removal spaces 210R and a plurality of gate recesses 250RS.

The plurality of gate structures 250 may include a plurality of gate dielectric layers 252 and a plurality of gate electrodes 254 covering the plurality of gate dielectric layers 252.

The plurality of gate dielectric layers 252 may be formed to conformally cover surfaces of the plurality of first semiconductor patterns 212R, surfaces of the plurality of second semiconductor patterns 214D, surfaces of the plurality of first insulating layers 230, and a surface of the second insulating layer 240, which are exposed within the remaining portions of the plurality of second removal spaces 210RS. The plurality of gate electrodes 254 may be formed to cover the plurality of gate dielectric layers 252 and fill the remaining portions of the plurality of second removal spaces 210RS. The gate dielectric layer 252 may be formed to surround at least a portion of the first semiconductor pattern 212R. For example, the gate dielectric layer 252 may be formed to cover upper and lower surfaces and both side surfaces in the second horizontal direction (Y direction) of at least a portion of the first semiconductor pattern 212R. The gate dielectric layer 252 may be formed to surround the second semiconductor pattern 214D. For example, the gate dielectric layer 252 may be formed to cover upper and lower surfaces and both side surfaces in the second horizontal direction (Y direction) of the second semiconductor pattern 214D.

The gate structure 250 may be formed to surround the first semiconductor patterns 212R and the second semiconductor patterns 214D and extend in the second horizontal direction (Y direction). When the second semiconductor pattern 214D is not present, when forming the gate electrode 254, a gap between the first semiconductor patterns 212R adjacent to one another in the second horizontal direction (Y direction) may be relatively large, and thus, voids in which the gate electrode 254 is not completely filled may occur within the gate electrode 254. However, when the second semiconductor pattern 214D is arranged between the first semiconductor patterns 212R adjacent to one another in the second horizontal direction (Y direction), a gap between the first semiconductor pattern 212R and the second semiconductor pattern 214D adjacent to one another in the second horizontal direction (Y direction) may be relatively small, and thus, voids may be prevented from occurring within the gate electrode 254.

The gate dielectric layer 252 may include at least one selected from silicon oxide, a high-k dielectric material having a higher dielectric constant than silicon oxide, and a ferroelectric material. For example, the high-k dielectric material and the ferroelectric material may include at least one material selected from hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO). For example, the gate dielectric layer 252 may include a metal oxide.

The gate electrode 254 may include a metal, a conductive metal nitride, or a combination thereof. In some embodiments, the gate electrode 254 may include a conductive barrier layer and a conductive filling layer covering the conductive barrier layer. The conductive barrier layer may include, for example, a metal, a conductive metal nitride, a conductive metal silicide, or a combination thereof. For example, the conductive barrier layer may include TiN. The conductive filling layer may include, for example, doped silicon, Ru, RuO, Pt, PtO, Ir, IrO, SrRuO (SRO), (Ba, Sr)RuO (BSRO), CaRuO (CRO), BaRuO, La(Sr, Co)O, Ti, TiN, W, WN, Ta, TaN, TiAlN, TiSiN, TaAlN, TaSiN, or a combination thereof. In some embodiments, the conductive filling layer may include W.

The plurality of gate recesses 250RS may be connected to the line trench LTR. The plurality of gate recesses 250RS may correspond to portions of the plurality of second removal spaces 210RS that are adjacent to the line trench LTR. For example, the plurality of gate recesses 250RS may be formed by removing a portion of the preliminary dielectric layer 252P and a portion of the preliminary electrode layer 254P that fill portions of the plurality of second removal spaces 210RS that are adjacent to the line trench LTR.

In some embodiments, a portion of the preliminary dielectric layer 252P and a portion of the preliminary electrode layer 254P that fill the line trench LTR, and a portion of the preliminary dielectric layer 252P and a portion of the preliminary electrode layer 254P that fill portions of the plurality of second removal spaces 210RS may be sequentially removed through a single process to form a plurality of gate structures 250 and a plurality of gate recesses 250RS.

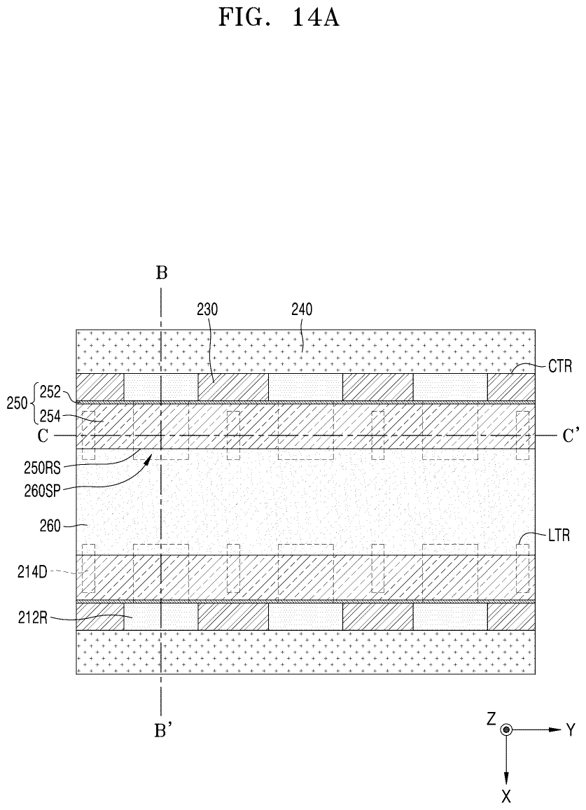

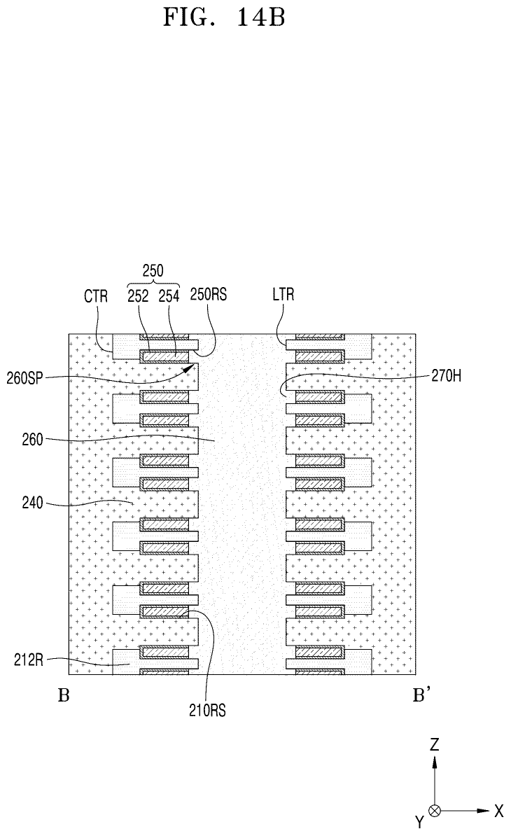

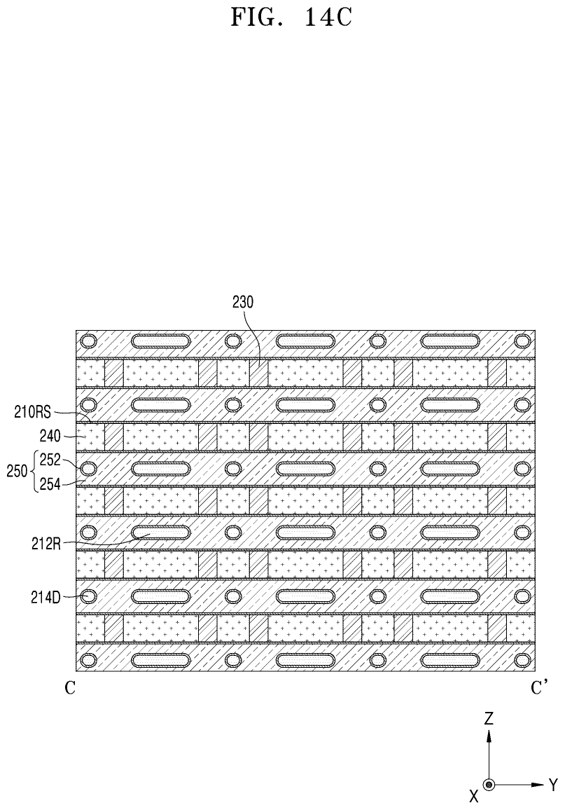

Referring to FIGS. 14A, 14B, 14C, a third insulating layer 260 is formed to fill the line trench LTR and the plurality of gate recesses 250RS. Portions of the third insulating layer 260 that fill the plurality of gate recesses 250RS may be referred to as a plurality of insulating spacers 260SP. The third insulating layer 260 may include oxide, nitride, oxynitride, carbonitride, or a combination thereof. In some embodiments, the third insulating layer 260 may include an insulating material having etch selectivity with respect to the second insulating layer 240.

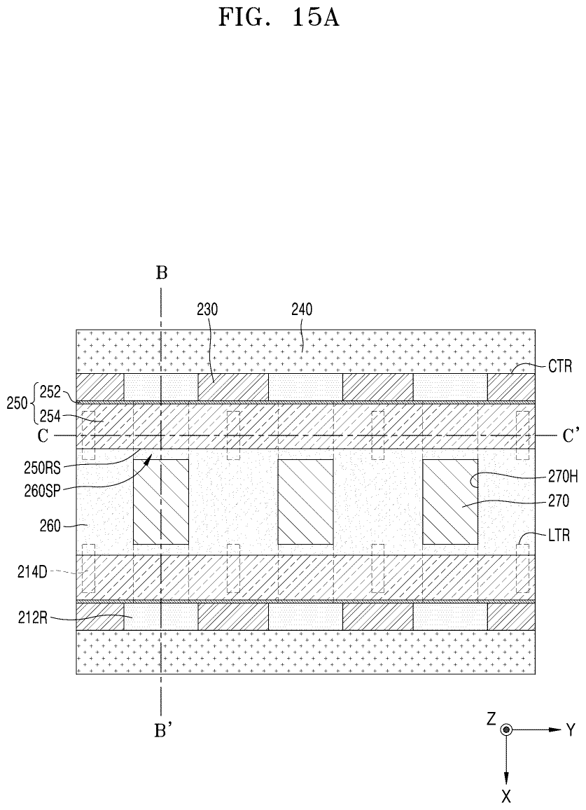

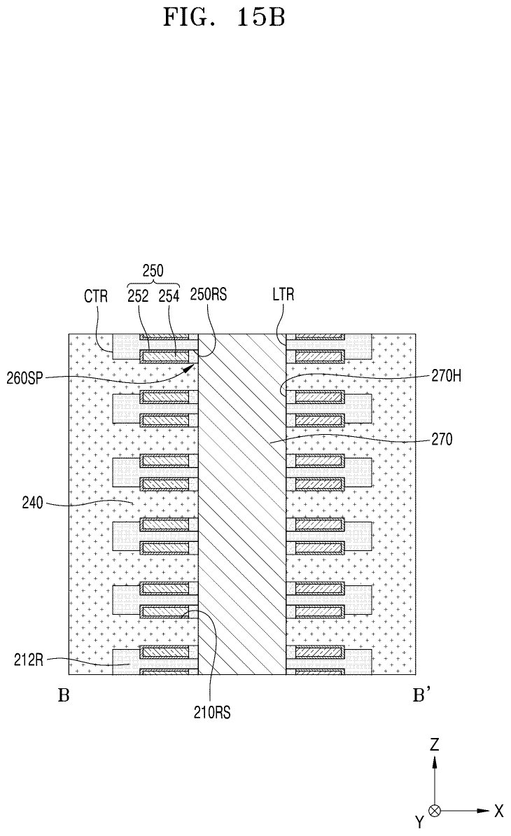

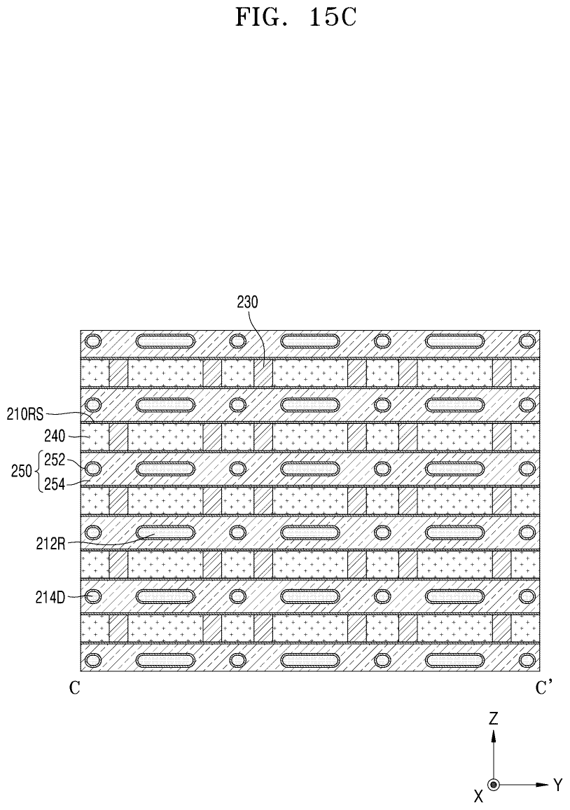

Referring to FIGS. 15A, 15B, and 15C, a plurality of bit line holes 270H penetrating the third insulating layer 260 and a plurality of bit lines 270 filling the plurality of bit line holes 270H are formed. The plurality of bit line holes 270H and the plurality of bit lines 270 extend in the vertical direction (Z direction) within the line trench LTR, and may be arranged spaced apart from one another in the second horizontal direction (Y direction). Ends of the plurality of first semiconductor patterns 212R may be exposed on inner side surfaces of the plurality of bit line holes 270H. For example, ends of the first semiconductor patterns 212R arranged spaced apart from one another in the vertical direction (Z direction) may be exposed on both inner side surfaces of each of the plurality of bit line holes 270H in the first horizontal direction (X direction). The plurality of bit line holes 270H may be formed such that the plurality of second semiconductor patterns 214D are not exposed within the plurality of bit line holes 270H. Each of the plurality of bit lines 270 may be connected to the ends of the first semiconductor patterns 212R arranged spaced apart from one another in the vertical direction (Z direction). The plurality of bit lines 270 may be electrically insulated from the plurality of second semiconductor patterns 214D by being spaced apart from the plurality of second semiconductor patterns 214D with the third insulating layer 260 therebetween. The bit line 270 may correspond to the bit line BL shown in FIG. 1.

The bit line 270 may include a conductive barrier layer that covers the inner side surfaces of the bit line hole 270H and is in contact with the ends of the first semiconductor pattern 212R, and a conductive filling layer that covers the conductive barrier layer. The conductive barrier layer may include, for example, a metal, a conductive metal nitride, a conductive metal silicide, or a combination thereof. For example, the conductive barrier layer may include TiN. The conductive filling layer may include, for example, doped silicon, Ru, RuO, Pt, PtO, Ir, IrO, SrRuO (SRO), (Ba, Sr)RuO (BSRO), CaRuO (CRO), BaRuO, La(Sr, Co)O, Ti, TiN, W, WN, Ta, TaN, TiAlN, TiSiN, TaAlN, TaSiN, or a combination thereof. In some embodiments, the conductive filling layer may include W.

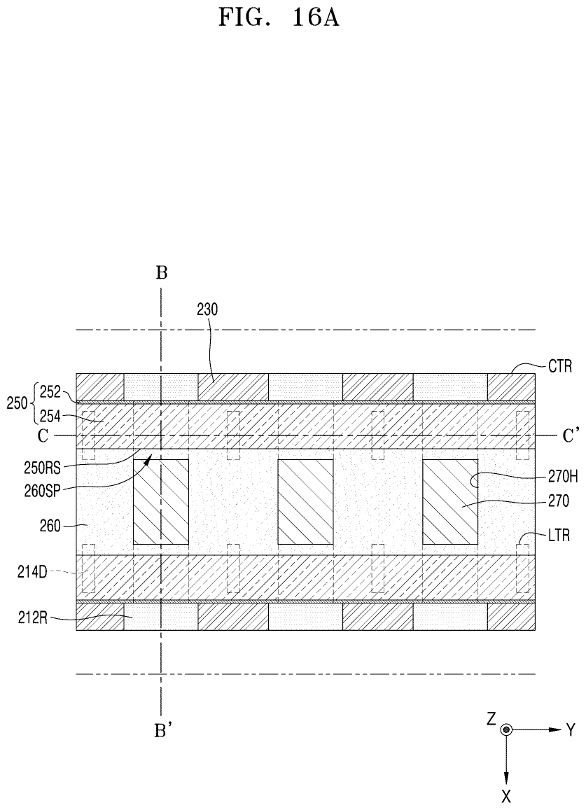

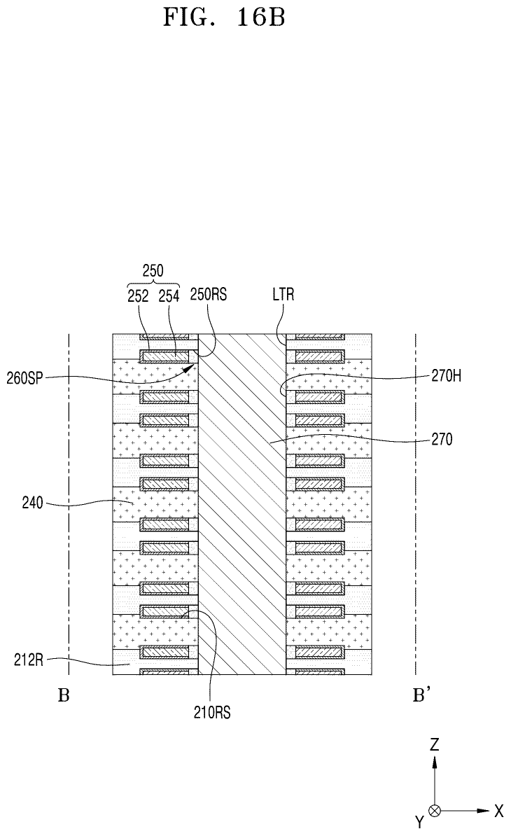

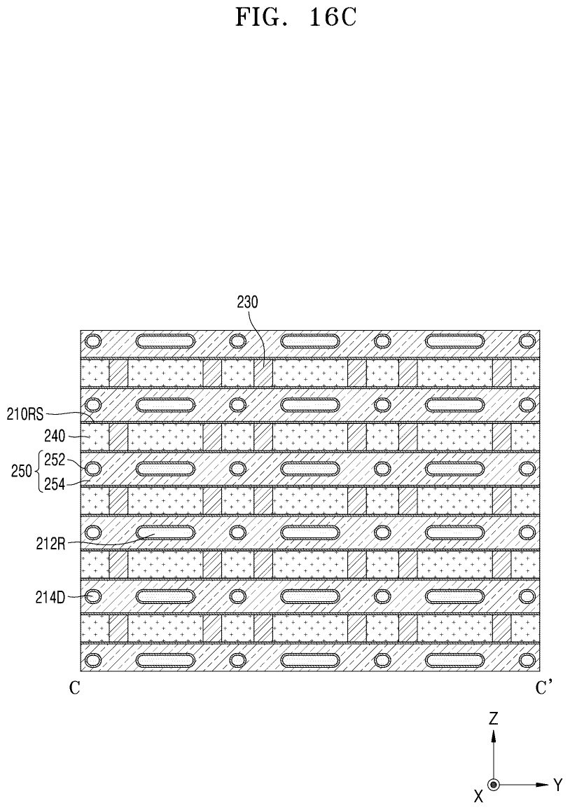

Referring to FIGS. 16A, 16B, and 16C, a portion of the second insulating layer 240 that fills the capacitor trench CTR is removed. The other ends of the plurality of first semiconductor patterns 212R that are opposite to the plurality of bit lines 270 may be exposed on the inner side surface of the capacitor trench CTR. The plurality of second semiconductor patterns 214D may not be exposed within the capacitor trench CTR. A plurality of first insulating layers 230 may be provided between the capacitor trench CTR and the plurality of second semiconductor patterns 214D. For example, within the capacitor trench CTR, the plurality of first semiconductor patterns 212R, the plurality of first insulating layers 230, and the second insulating layer 240 may be exposed, but the plurality of second semiconductor patterns 214D may not be exposed.

Thereafter, referring to FIGS. 3A, 3B, 3C, and 3D, a plurality of capacitor structures 280 including a plurality of first electrodes 282, a capacitor dielectric layer 284 covering the plurality of first electrodes 282, and a second electrode 286 covering the capacitor dielectric layer 284 are formed on the other ends of the plurality of first semiconductor patterns 212R. The plurality of first electrodes 282 may be formed to be in contact with the other ends of the plurality of first semiconductor patterns 212R corresponding thereto. The capacitor dielectric layer 284 may be formed to conformally cover the plurality of first electrodes 282. The plurality of first electrodes 282 may be electrically insulated from the plurality of second semiconductor patterns 214D by being spaced apart from the plurality of second semiconductor patterns 214D with the plurality of first insulating layers 230 therebetween. FIGS. 3A and 3B show that the capacitor dielectric layers 284 respectively covering the plurality of first electrodes 282 are formed to be separated from one another, but this is merely an example, and embodiments are not limited thereto. For example, the capacitor dielectric layer 284 may be formed as a single body within the capacitor trench CTR to conformally cover the plurality of first electrodes 282, the plurality of first insulating layers 230, and the second insulating layer 240. The second electrode 286 may be formed to cover at least some of the plurality of first electrodes 282 with the capacitor dielectric layer 284 therebetween. In some embodiments, the second electrode 286 may be formed as a single body within the capacitor trench CTR to conformally cover the plurality of first electrodes 282, the plurality of first insulating layers 230, and the second insulating layer 240 with the capacitor dielectric layer 284 therebetween.

The first electrode 282 may include a metal or a conductive metal nitride. For example, the first electrode 282 may include a high-melting point metal, such as cobalt, titanium, nickel, tungsten, and molybdenum, and/or a conductive metal nitride, such as titanium nitride, titanium silicon nitride, titanium aluminum nitride, tantalum nitride, tantalum silicon nitride, tantalum aluminum nitride, and tungsten nitride. The capacitor dielectric layer 284 may include at least one selected from a high-k dielectric material, which has a higher dielectric constant than silicon oxide, and a ferroelectric material. For example, the capacitor dielectric layer 284 may include at least one of a metal oxide and a dielectric material having a perovskite structure. In some embodiments, the capacitor dielectric layer 284 may include at least one material selected from hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO). For example, the second electrode 286 may include doped silicon, Ru, RuO, Pt, PtO, Ir, IrO, SrRuO (SRO), (Ba, Sr)RuO (BSRO), CaRuO (CRO), BaRuO, La(Sr, Co)O, Ti, TiN, W, WN, Ta, TaN, TiAlN, TiSiN, TaAlN, TaSiN, or a combination thereof. In some embodiments, the second electrode 286 may include W.

Thereafter, a fourth insulating layer 290 covering the plurality of capacitor structures 280 and filling the capacitor trench CTR may be formed, to thereby form a semiconductor memory device 1. The fourth insulating layer 290 may include oxide, nitride, oxynitride, carbonitride, or a combination thereof.

In the method of manufacturing the semiconductor memory device 1 according to the disclosed concepts, because the gate structure 250 is formed after the second semiconductor pattern 214D is formed between the first semiconductor patterns 212R adjacent to one another in the second horizontal direction (Y direction), in the process of forming the gate electrode 254 included in the gate structure 250, voids may be prevented from occurring within the gate electrode 254. Accordingly, the gate electrode 254 may be prevented from becoming thin or broken due to voids.

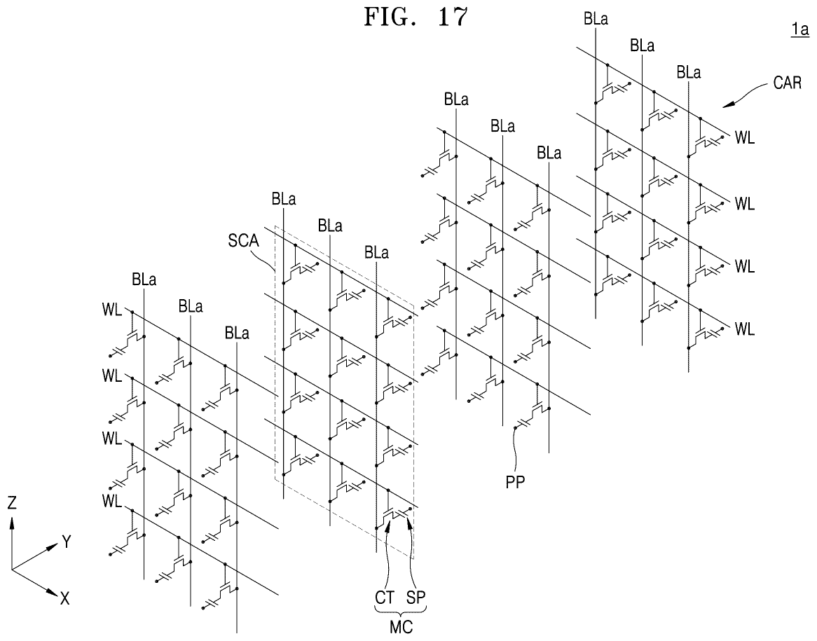

FIG. 17 is an equivalent circuit diagram illustrating a memory cell array of a semiconductor memory device la according to embodiments.

Referring to FIG. 17, a memory cell array CAR of the semiconductor memory device la according to embodiments may include a plurality of sub-cell arrays SCA. The sub-cell array SCA may include a plurality of bit lines BLa, a plurality of word lines WL, and a plurality of memory cells MC. Each of the plurality of memory cells MC may include a cell transistor CT and an information storage element SP. One cell transistor CT may be arranged between one word line WL and one bit line BLa. The plurality of sub-cell arrays SCA may be arranged in the second horizontal direction (Y direction).

The plurality of word lines WL may extend in the first horizontal direction (X direction). The word lines WL within one sub-cell array SCA may be spaced apart from one another in the vertical direction (Z direction). The bit line BLa may extend in the vertical direction (Z direction). The bit lines BLa within one sub-cell array SCA may be spaced apart from one another in the first horizontal direction (X direction). Two sub-cell arrays SCA adjacent to one another in the second horizontal direction (Y direction) may not share bit lines BLa.

A gate of the cell transistor CT may be connected to the word line WL, and a source region of the cell transistor CT may be connected to the bit line BLa. The information storage element SP may be connected to a drain region of the cell transistor CT.

In some embodiments, the source region and drain region of the cell transistor CT and the information storage element SP may be arranged in the second horizontal direction (Y direction) or a direction opposite to the second horizontal direction (Y direction), from the bit line BLa connected to the source region of the cell transistor CT. The source region and drain region of the cell transistor CT connected to one of two bit lines BLa adjacent to one another in the second horizontal direction (Y direction) and the information storage element SP connected to the cell transistor CT may be sequentially arranged in a direction opposite to a direction in which the source region and drain region of the cell transistor CT connected to the other bit line BLa, and the information storage element SP connected to the cell transistor CT may be sequentially arranged. For example, the source region and drain region of the cell transistor CT connected to one of the two bit lines BLa adjacent to one another in the second horizontal direction (Y direction), and the information storage element SP connected to the cell transistor CT may be sequentially arranged in the second horizontal direction (Y direction), and the source region and drain region of the cell transistor CT connected to the other bit line BLa, and the information storage element SP connected to the cell transistor CT may be sequentially arranged in a direction opposite to the second horizontal direction (Y direction). For example, the plurality of bit lines BLa may include a first bit line, a second bit line, a third bit line, and a fourth bit line that are sequentially arranged adjacent to one another in the second horizontal direction (Y direction), wherein a memory cell MC may not be arranged between the first bit line and the second bit line, two memory cells MC may be arranged between the second bit line and the third bit line at the same vertical level in the second horizontal direction (Y direction), and a memory cell MC may not be arranged between the third bit line and the fourth bit line.

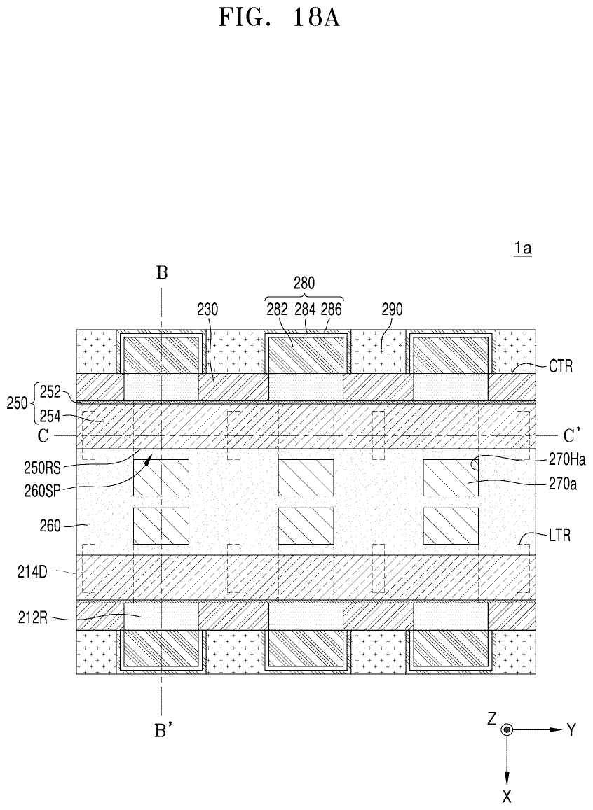

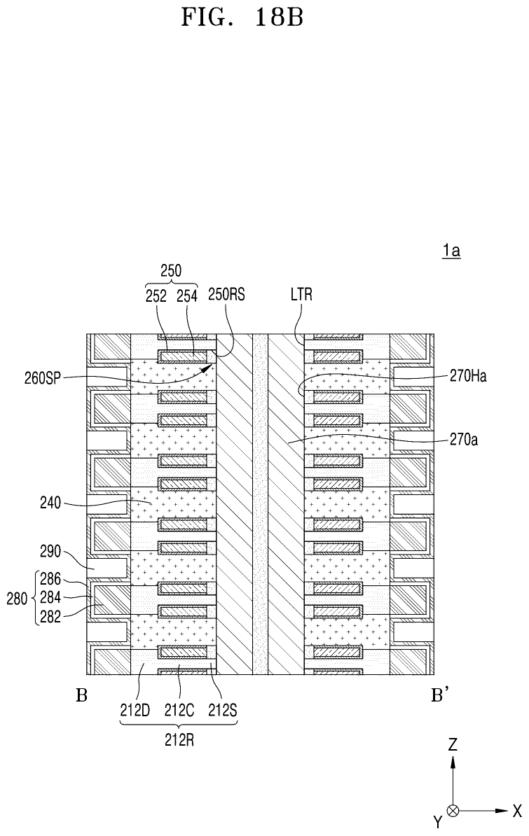

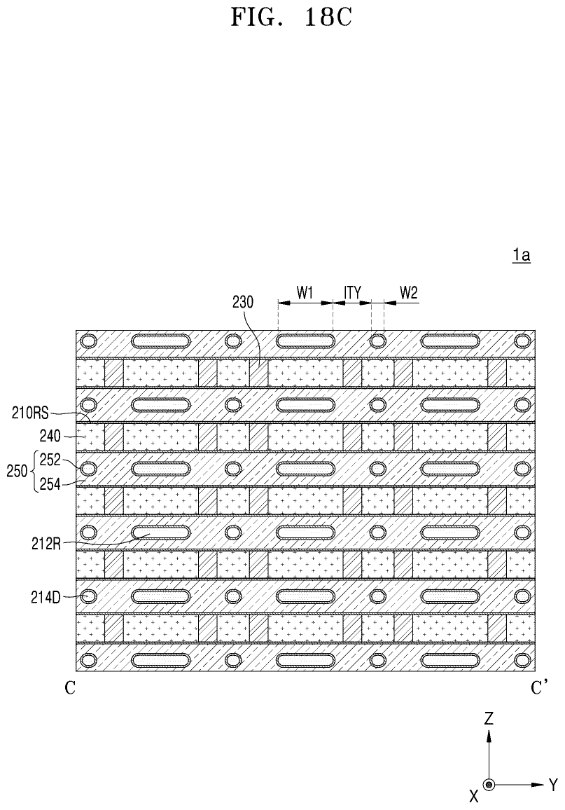

FIGS. 18A, 18B, and 18C are diagrams illustrating the semiconductor memory device la according to embodiments. In detail, FIG. 18A is a plan layout view illustrating main components of the semiconductor memory device la, FIG. 18B is a cross-sectional view of the semiconductor memory device la, taken along line B-B′ of FIG. 18A, and FIG. 18C is a cross-sectional view of the semiconductor memory device la, taken along line C-C′ of FIG. 18A. A cross-sectional view of the semiconductor memory device 1 a shown in FIGS. 18A, 18B, and 18C, taken along a position corresponding to the line D-D′ of FIG. 3A, is substantially the same as FIG. 3D, and thus, FIG. 3D may also be referred to below.

Referring to FIGS. 18A, 18B, 18C, and 3D, the semiconductor memory device la may include a plurality of first semiconductor patterns 212R, a plurality of second semiconductor patterns 214D, a plurality of gate dielectric layers 252 surrounding at least portions of the plurality of first semiconductor patterns 212R and the plurality of second semiconductor patterns 214D, a plurality of gate electrodes 254 surrounding at least portions of the plurality of first semiconductor patterns 212R and the plurality of second semiconductor patterns 214D with the plurality of gate dielectric layers 252 therebetween, a plurality of bit lines 270a connected to ends of the plurality of first semiconductor patterns 212R, and a plurality of capacitor structures 280 connected to the other ends of the plurality of first semiconductor patterns 212R.

Each of the plurality of first semiconductor patterns 212R and the plurality of second semiconductor patterns 214D may extend in the first horizontal direction (X direction). The plurality of first semiconductor patterns 212R may be arranged spaced apart from one another in each of the first horizontal direction (X direction), the second horizontal direction (Y direction), and the vertical direction (Z direction). The plurality of first semiconductor patterns 212R may have matrix forms that are arranged in a line in each of the first horizontal direction (X direction) and the second horizontal direction (Y direction) in a plan view, and may arranged to be aligned in the vertical direction (Z direction). The plurality of second semiconductor patterns 214D may be arranged spaced apart from one another in each of the first horizontal direction (X direction), the second horizontal direction (Y direction), and the vertical direction (Z direction). The second semiconductor pattern 214D may be arranged between a pair of first semiconductor patterns 212R adjacent to one another in the second horizontal direction (Y direction). For example, the first semiconductor patterns 212R and the second semiconductor patterns 214D may be alternately arranged spaced apart from one another in the second horizontal direction (Y direction).

The first semiconductor pattern 212R may include a first portion 212C, a second portion 212S, and a third portion 212D. The second portion 212S and the third portion 212D may be respectively located on both sides of the first portion 212C in the first horizontal direction (X direction). The second portion 212S, the first portion 212C, and the third portion 212D may be sequentially arranged in the first horizontal direction (X direction) from the bit line 270a to the capacitor structure 280. The first portion 212C of the first semiconductor pattern 212R may be surrounded by a gate structure 250, the second portion 212S of the first semiconductor pattern 212R may be surrounded by an insulating spacer 260SP and connected to the bit line 270a, and the third portion 212D of the first semiconductor pattern 212R may be surrounded by a first insulating layer 230 and a second insulating layer 240, that is, the interlayer insulating layer described above, and connected to a first electrode 282 of the capacitor structure 280.

In the first horizontal direction (X direction), an end of the first semiconductor pattern 212R may be in contact with the bit line 270a, and an end of the second semiconductor pattern 214D may be in contact with a third insulating layer 260. In the first horizontal direction (X direction), the other end of the first semiconductor pattern 212R may be in contact with the first electrode 282 of the capacitor structure 280, and the other end of the second semiconductor pattern 214D may be in contact with the first insulating layer 230.

Each of the plurality of gate electrodes 254 may extend in the second horizontal direction (Y direction). The plurality of bit lines 270a may be connected to ends of the plurality of first semiconductor patterns 212R in the first horizontal direction (X direction), and the plurality of capacitor structures 280 may be connected to the other ends of the plurality of first semiconductor patterns 212R in the first horizontal direction (X direction). The gate electrode 254 may be the word line WL shown in FIG. 17. The bit line 270a may be the bit line BLa shown in FIG. 17. The capacitor structure 280 may be the information storage element SP shown in FIG. 17. The first semiconductor pattern 212R, the gate dielectric layer 252, the gate electrode 254, and the bit line 270a may form the cell transistor CT shown in FIG. 17. The gate electrode 254 may be spaced apart from the bit line 270a with the third insulating layer 260 including the insulating spacer 260SP therebetween.

The second portion 212S, the first portion 212C, and the third portion 212D of the first semiconductor pattern 212R may be sequentially arranged from the bit line 270a in the second horizontal direction (Y direction) or a direction opposite to the second horizontal direction (Y direction).

The third insulating layer 260 may surround the plurality of bit lines 270a, and may fill a line trench LTR. The plurality of bit lines 270a may fill a plurality of bit line holes 270Ha penetrating the third insulating layer 260. The plurality of bit lines 270a may be connected to ends of the plurality of first semiconductor patterns 212R in the first horizontal direction (X direction). The plurality of bit line holes 270Ha and the plurality of bit lines 270a may extend in the vertical direction (Z direction) within the line trench LTR. Within the line trench LTR, a pair of bit line holes 270Ha spaced apart from one another in the first horizontal direction (X direction) and a pair of bit lines 270a filling the pair of bit line holes 270Ha may be arranged spaced apart from one another in a line in the second horizontal direction (Y direction).

The plurality of capacitor structures 280 may include a plurality of first electrodes 282, a capacitor dielectric layer 284, and a second electrode 286. The plurality of capacitor structures 280 may be connected to the other ends of the plurality of first semiconductor patterns 212R in the first horizontal direction (X direction). A fourth insulating layer 290 may cover the plurality of capacitor structures 280, and may fill a capacitor trench CTR.

While the disclosed concepts have been particularly shown and described with reference to embodiments thereof, it will be understood that various changes in form and details may be made therein without departing from the spirit and scope of the following claims.

What is claimed is:

1. A semiconductor memory device comprising:
a first semiconductor pattern extending in a first horizontal direction;
a second semiconductor pattern having a horizontal width that is less than a horizontal width of the first semiconductor pattern in a second horizontal direction, being spaced apart from the first semiconductor pattern in the second horizontal direction, and extending in the first horizontal direction, the second horizontal direction being substantially orthogonal to the first horizontal direction;
a gate structure surrounding the first semiconductor pattern and the second semiconductor pattern and extending in the second horizontal direction;
a bit line connected to an end of the first semiconductor pattern in the first horizontal direction and extending in a vertical direction; and
a capacitor structure connected to another end of the first semiconductor pattern in the first horizontal direction,
wherein the second semiconductor pattern is spaced apart from each of the bit line and the capacitor structure.

2. The semiconductor memory device of claim 1, wherein, in the first horizontal direction, a length of the first semiconductor pattern is greater than a length of the second semiconductor pattern.

3. The semiconductor memory device of claim 2, wherein, in the first horizontal direction, the end of the first semiconductor pattern is aligned with an end of the second semiconductor pattern in the second horizontal direction.

4. The semiconductor memory device of claim 1, wherein, in the second horizontal direction, the first semiconductor pattern and the second semiconductor pattern are spaced apart from one another by a pattern interval that is less than the horizontal width of the first semiconductor pattern and greater than the horizontal width of the second semiconductor pattern.

5. The semiconductor memory device of claim 1, further comprising a line trench filling insulating layer surrounding the bit line,
wherein an end of the second semiconductor pattern in the first horizontal direction is in contact with the line trench filling insulating layer and is electrically insulated from the bit line.

6. The semiconductor memory device of claim 5, further comprising an interlayer insulating layer surrounding the first semiconductor pattern, the second semiconductor pattern, and the gate structure,
wherein the first semiconductor pattern includes a first portion, a second portion, and a third portion, the first portion being surrounded by the gate structure, the second portion being surrounded by the line trench filling insulating layer and connected to the bit line, and the third portion being surrounded by the interlayer insulating layer and connected to the capacitor structure, and
the second portion, the first portion, and the third portion of the first semiconductor pattern are sequentially arranged in the first horizontal direction from the bit line to the capacitor structure.

7. The semiconductor memory device of claim 6, wherein, in the first horizontal direction, a length of the first portion is greater than each of a length of the second portion and a length of the third portion.

8. The semiconductor memory device of claim 6, wherein, in the second horizontal direction, a horizontal width of the third portion is greater than each of a horizontal width of the first portion and a horizontal width of the second portion.

9. The semiconductor memory device of claim 6, wherein, in the vertical direction, a thickness of the third portion is greater than each of a thickness of the first portion and a thickness of the second portion.

10. The semiconductor memory device of claim 9, wherein, in the vertical direction, a thickness of the second semiconductor pattern is equal to each of the thickness of the first portion and the thickness of the second portion.

11. A semiconductor memory device comprising:
a plurality of first semiconductor patterns each extending in a first horizontal direction and arranged spaced apart from one another in each of a second horizontal direction and a vertical direction, the second horizontal direction being substantially orthogonal to the first horizontal direction;
a plurality of second semiconductor patterns each extending in the first horizontal direction, each having a horizontal width that is less than a horizontal width of each of the plurality of first semiconductor patterns in the second horizontal direction, arranged spaced apart from one another in each of the second horizontal direction and the vertical direction, and alternately arranged spaced apart from the plurality of first semiconductor patterns in the second horizontal direction;
a plurality of gate structures surrounding the plurality of first semiconductor patterns and the plurality of second semiconductor patterns, each extending in the second horizontal direction, and arranged spaced apart from one another in the vertical direction;
an interlayer insulating layer surrounding the plurality of first semiconductor patterns, the plurality of second semiconductor patterns, and the plurality of gate structures;
a plurality of bit lines connected to ends of first semiconductor patterns arranged spaced apart from one another in the vertical direction, among the plurality of first semiconductor patterns, in the first horizontal direction, each extending in the vertical direction, and arranged spaced apart from one another in the second horizontal direction;
a line trench filling insulating layer surrounding the plurality of bit lines;
a plurality of capacitor structures connected to other ends of the plurality of first semiconductor patterns in the first horizontal direction; and
a capacitor trench filling insulating layer surrounding the plurality of capacitor structures,
wherein the plurality of second semiconductor patterns are spaced apart from the plurality of bit lines and the plurality of capacitor structures.

12. The semiconductor memory device of claim 11, wherein, in the first horizontal direction, ends of the plurality of first semiconductor patterns are aligned with ends of the plurality of second semiconductor patterns in the second horizontal direction, and
in the first horizontal direction, a length of each of the plurality of first semiconductor patterns is greater than a length of each of the plurality of second semiconductor patterns.

13. The semiconductor memory device of claim 11, wherein, in the first horizontal direction, ends of the plurality of second semiconductor patterns are in contact with the line trench filling insulating layer and are electrically insulated from the plurality of bit lines, and other ends of the plurality of second semiconductor patterns are in contact with the interlayer insulating layer and are electrically insulated from the plurality of capacitor structures.

14. The semiconductor memory device of claim 11, wherein each of the plurality of first semiconductor patterns includes a first portion, a second portion, and a third portion, the first portion being surrounded by one of the plurality of gate structures, the second portion being surrounded by the line trench filling insulating layer and connected to one of the plurality of bit lines, and the third portion being surrounded by the interlayer insulating layer and connected to one of the plurality of capacitor structures,
the second portion, the first portion, and the third portion of each of the plurality of first semiconductor patterns are sequentially arranged in the first horizontal direction from one of the plurality of bit lines to one of the plurality of capacitor structures, and
in the first horizontal direction, a length of the first portion is greater than each of a length of the second portion and a length of the third portion.

15. The semiconductor memory device of claim 14, wherein each of the plurality of second semiconductor patterns includes a first dummy portion and a second dummy portion, the first dummy portion being surrounded by one of the plurality of gate structures, and the second dummy portion being surrounded by the line trench filling insulating layer, and
in the first horizontal direction, a length of the first dummy portion of each of the plurality of second semiconductor patterns is greater than a length of the second dummy portion and less than the length of the first portion of each of the plurality of first semiconductor patterns.

16. The semiconductor memory device of claim 15, wherein, in the first horizontal direction, the length of the second dummy portion of each of the plurality of second semiconductor patterns is equal to the length of the second portion of each of the plurality of first semiconductor patterns.

17. The semiconductor memory device of claim 14, wherein, in the second horizontal direction, a horizontal width and a thickness of the third portion are greater than a horizontal width and a thickness of the first portion and a horizontal width and a thickness of the second portion, respectively.

18. A semiconductor memory device comprising:
a plurality of first semiconductor patterns each extending in a first horizontal direction and arranged spaced apart from one another in each of a second horizontal direction and a vertical direction, the second horizontal direction being substantially orthogonal to the first horizontal direction;
a plurality of second semiconductor patterns each extending in the first horizontal direction, each having a horizontal width that is less than a horizontal width of each of the plurality of first semiconductor patterns in the second horizontal direction, arranged spaced apart from one another in each of the second horizontal direction and the vertical direction, and alternately arranged spaced apart from the plurality of first semiconductor patterns in the second horizontal direction;
a plurality of gate structures surrounding the plurality of first semiconductor patterns and the plurality of second semiconductor patterns, each extending in the second horizontal direction, and arranged spaced apart from one another in the vertical direction;
an interlayer insulating layer surrounding the plurality of first semiconductor patterns, the plurality of second semiconductor patterns, and the plurality of gate structures;
a plurality of bit lines connected to ends of first semiconductor patterns arranged spaced apart from one another in the vertical direction, among the plurality of first semiconductor patterns, in the first horizontal direction, each extending in the vertical direction, and arranged spaced apart from one another in the second horizontal direction;
a line trench filling insulating layer surrounding the plurality of bit lines;
a plurality of capacitor structures connected to other ends of the plurality of first semiconductor patterns in the first horizontal direction; and
a capacitor trench filling insulating layer surrounding the plurality of capacitor structures,
wherein, in the first horizontal direction, ends of the plurality of second semiconductor patterns are in contact with the line trench filling insulating layer, and other ends of the plurality of second semiconductor patterns are in contact with the interlayer insulating layer.

19. The semiconductor memory device of claim 18, wherein each of the plurality of first semiconductor patterns includes a first portion, a second portion, and a third portion, the first portion being surrounded by one of the plurality of gate structures, the second portion being surrounded by the line trench filling insulating layer and connected to one of the plurality of bit lines, and the third portion being surrounded by the interlayer insulating layer and connected to one of the plurality of capacitor structures,
each of the plurality of second semiconductor patterns includes a first dummy portion and a second dummy portion, the first dummy portion being surrounded by one of the plurality of gate structures, and the second dummy portion being surrounded by the line trench filling insulating layer,
in the first horizontal direction, a length of the first dummy portion of each of the plurality of second semiconductor patterns is greater than a length of the second dummy portion and less than a length of the first portion of each of the plurality of first semiconductor patterns, and
in the first horizontal direction, the length of the second dummy portion of each of the plurality of second semiconductor patterns is equal to a length of the second portion of each of the plurality of first semiconductor patterns.

20. The semiconductor memory device of claim 19, wherein, in the second horizontal direction, a horizontal width of the third portion of each of the plurality of first semiconductor patterns is greater than each of a horizontal width of the first portion and a horizontal width of the second portion, and
in the vertical direction, a thickness of the third portion of each of the plurality of first semiconductor patterns is greater than each of a thickness of the first portion and a thickness of the second portion.
